(19) United States
(12) Patent Application Publication
(10) Pub. No.: US 2025/0241152 A1
(43) Pub. Date: Jul. 24, 2025

(54) DISPLAY APPARATUS

(71) Applicant: SAMSUNG DISPLAY CO., LTD., Yongin-si (KR)

(72) Inventors: Minki YANG, Yongin-si (KR); Changkyu JIN, Yongin-si (KR); Daehyun KIM, Yongin-si (KR); Sunghwan KIM, Yongin-si (KR); Kyoungjin PARK, Yongin-si (KR); Heyjin SHIN, Yongin-si (KR); Hyeonjun YOON, Yongin-si (KR); Hwansoo JANG, Yongin-si (KR)

(21) Appl. No.: 19/015,792

(22) Filed: Jan. 10, 2025

(30) Foreign Application Priority Data
Jan. 24, 2024 (KR) 10-2024-0011239
Jun. 13, 2024 (KR) 10-2024-0077166

(51) Int. Cl. H10K 59/131; H10D 86/40; H10K 59/121; H10K 59/126

(52) U.S. Cl. CPC H10K 59/131; H10K 59/1213; H10K 59/126; H10D 86/441

(57) ABSTRACT

A display apparatus includes a first conductive layer including a first initialization voltage line extending in a first direction, a first semiconductor layer, a second conductive layer including a first gate electrode, a third conductive layer including a first connection electrode electrically connecting the first semiconductor layer to the first initialization voltage line, and a first data connection line extending in the first direction, and a fourth conductive layer including a driving voltage line extending in a second direction crossing the first direction and a second data connection line. The driving voltage line has a hole defined therein. The hole overlaps the first connection electrode. The driving voltage line includes a shielding portion that overlaps the first data connection line.

### CROSS-REFERENCE TO RELATED APPLICATION

This application claims priority under 35 U.S.C. § 119 to Korean Patent Application No. 10-2024-0011239, filed on Jan. 24, 2024 in the Korean Intellectual Property Office (KIPO) and Korean Patent Application No. 10-2024-0077166, filed on Jun. 13, 2024 in KIPO, the disclosures of which are incorporated by reference in their entireties herein.

### 1. TECHNICAL FIELD

One or more embodiments relate to a display apparatus.

### 2. DISCUSSION OF RELATED ART

In recent years, display apparatuses have become increasingly thin and light and the range of use of display apparatuses has diversified. A display apparatus may include a plurality of pixels. Each of the plurality of pixels may include a light-emitting diode and a pixel circuit for controlling the brightness of the light-emitting diode. The pixel circuit may include transistors and capacitors, which are connected to wirings such as data lines, gate signal lines, voltage lines, and the like.

As display apparatuses become more widely used and the number of functions that may be connected with or linked to the display apparatuses has increased, various types of display apparatuses have been developed.

### SUMMARY

However, in a display apparatus according to the related art, the coupling between a data connection line that transmits a data signal to a data line and a pixel electrode of a light-emitting diode causes specks in an image displayed by the display apparatus due to a difference in the brightness of pixels of the display apparatus.

One or more embodiments include a display apparatus displaying high-quality images by reducing coupling between a data connection line and a pixel electrode. However, this objective is merely illustrative, and the scope of embodiments of the present disclosure are not limited thereto.

Additional aspects will be set forth in part in the description which follows and, in part, will be apparent from the description, or may be learned by practice of the presented embodiments of the disclosure.

According to an embodiment a display apparatus includes a first conductive layer disposed on a substrate. The first conductive layer comprises a first initialization voltage line extending in a first direction. A first semiconductor layer is disposed on the first conductive layer. A second conductive layer is disposed on the first semiconductor layer. The second conductive layer comprises a first gate electrode. A third conductive layer is disposed on the second conductive layer. The third conductive layer comprises a first connection electrode electrically connecting the first semiconductor layer and the first initialization voltage line to each other and a first data connection line extending in the first direction. A fourth conductive layer is disposed on the third conductive layer. The fourth conductive layer comprises a driving voltage line extending in a second direction crossing the first direction and a second data connection line. The driving voltage line has a hole defined therein. The hole overlaps the first connection electrode. The driving voltage line includes a shielding portion that overlaps the first data connection line.

In an embodiment, the first initialization voltage line may include a first portion and a second portion protruding from the first portion in the second direction, the first semiconductor layer may include a first portion extending in the first direction and a second portion protruding from the first portion in the second direction, and the first connection electrode may electrically connect the second portion of the first initialization voltage line and the second portion of the first semiconductor layer to each other.

In an embodiment, the first portion of the first initialization voltage line may overlap the first portion of the first semiconductor layer.

In an embodiment, the fourth conductive layer may further include a second connection electrode overlapping the hole, and the first connection electrode may be disposed between the second connection electrode and the first data connection line.

In an embodiment, the display apparatus may further include a fifth conductive layer disposed on the fourth conductive layer and including a pixel electrode, and the pixel electrode may be electrically connected to the second connection electrode.

In an embodiment, the pixel electrode may overlap the first data connection line, and the shielding portion may be disposed between the pixel electrode and the first data connection line.

In an embodiment, the third conductive layer may further include a second initialization voltage line extending in the first direction, and the first connection electrode may be disposed between the first data connection line and the second initialization voltage line.

In an embodiment, the fourth conductive layer may further include a data line extending in the second direction, and the first data connection line may be electrically connected to the data line and the second data connection line.

In an embodiment, the substrate may include a display area and a peripheral area outside the display area, and the first data connection line may be electrically connected to the data line in the display area.

In an embodiment, the display apparatus may further include a second semiconductor layer disposed between the substrate and the first conductive layer, and the first semiconductor layer may include an oxide-based semiconductor material, and the second semiconductor layer may include a silicon-based semiconductor material.

According to an embodiment of the present disclosure, a display apparatus includes a plurality of pixels, a first data connection line extending in a first direction, a second data connection line extending in a second direction crossing the first direction, and a driving voltage line extending in the second direction. The driving voltage line has a hole defined therein. A shielding portion overlaps the first data connection line. Each of the plurality of pixels may include a light-emitting diode including a pixel electrode, an opposite electrode, and an intermediate layer between the pixel electrode and the opposite electrode, a first transistor including a first semiconductor layer and a first gate electrode on the first semiconductor layer, a second transistor electrically connected between a data line and the first transistor, a third transistor electrically connected between a first initialization voltage line and the first gate electrode, a fourth transistor electrically connected between the driving voltage line and the first transistor, a fifth transistor electrically connected to the first transistor and the light-emitting diode, and a first connection electrode electrically connecting the first initialization voltage line to the third transistor and overlapping the hole.

In an embodiment, each of the plurality of pixels may further include a second connection electrode electrically connected between the pixel electrode and the fifth transistor, and the second connection electrode may overlap the hole.

In an embodiment, the first connection electrode may be disposed between the second connection electrode and the first data connection line.

In an embodiment, the pixel electrode may overlap the first data connection line, and the shielding portion may be disposed between the pixel electrode and the first data connection line.

In an embodiment, the light-emitting diode may emit green light.

In an embodiment, the first data connection line may be disposed in the same layer as the first connection electrode.

In an embodiment, each of the plurality of pixels may further include a sixth transistor electrically connected between a second initialization voltage line and the light-emitting diode.

In an embodiment, the second initialization voltage line may extend in the first direction, and the first connection electrode may be disposed between the first initialization voltage line and the first data connection line.

In an embodiment, the first data connection line may be electrically connected to the data line and the second data connection line.

In an embodiment, the display apparatus may further include an on-bias voltage line extending in the first direction, and each of the plurality of pixels may further include a seventh transistor electrically connected between the on-bias voltage line and the first transistor.

Other aspects, features, and advantages other than the above description will be clear from the details of the drawings, the claim of claims and the details of embodiments of the present disclosure.

### BRIEF DESCRIPTION OF THE DRAWINGS

The above and other aspects, features, and advantages of certain non-limiting embodiments of the present disclosure will be more apparent from the following description taken in conjunction with the accompanying drawings, in which:

FIG. 1 is a plan view schematically illustrating a portion of a display apparatus according to an embodiment of the present disclosure;

FIG. 2 is a plan view schematically illustrating a portion of a display apparatus according to an embodiment of the present disclosure;

FIGS. 3A and 3B are respectively plan views schematically illustrating a portion of the display apparatus shown in FIG. 2 according to embodiments of the present disclosure;

FIGS. 4A and 4B are respectively plan views schematically illustrating a portion of the display apparatus shown in FIG. 2 according to embodiments of the present disclosure;

FIG. 5 is an equivalent circuit diagram of one pixel of a display apparatus according to an embodiment of the present disclosure;

FIG. 6 is an arrangement view schematically illustrating a portion of a display apparatus according to an embodiment of the present disclosure;

FIGS. 7 through 13 are arrangement views schematically illustrating a portion of the display apparatus shown in FIG. 6 according to layers according to embodiments of the present disclosure;

FIG. 14 is an enlarged plan view schematically illustrating a portion of the display apparatus shown in FIG. 6 according to an embodiment of the present disclosure; and

FIG. 15 is a cross-sectional view schematically illustrating a portion of the display apparatus shown in FIG. 14 according to an embodiment of the present disclosure.

### DETAILED DESCRIPTION OF EMBODIMENTS

Reference will now be made in detail to non-limiting embodiments, examples of which are illustrated in the accompanying drawings, wherein like reference numerals refer to like elements throughout. In this regard, embodiments of the present disclosure may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since various modifications and various embodiments are possible, non-limiting embodiments are illustrated in the drawings and described in detail in the detailed description. Effects and features of the present disclosure, and a method of achieving them will be apparent with reference to embodiments described below in detail in conjunction with the drawings. However, the present disclosure is not limited to the embodiments described herein, but may be implemented in a variety of forms.

Hereinafter, embodiments will be described in detail with reference to the accompanying drawings, and the same or corresponding components are denoted by the same reference numerals, and the same reference numerals are assigned and redundant explanations will be omitted.

In the present specification, the terms of the first and second, etc. are used for the purpose of distinguishing one element from other elements, and not in a limiting sense.

In the present specification, the singular expression includes a plurality of expressions unless the context is clearly different.

In the present specification, the terms such as comprising or having are meant to be the features described in the specification, or the elements are present, and the possibility of one or more other features or elements that may be added, is not excluded.

In the present specification, when a portion such as a layer, a region, an element or the like is on other portions, this is not only when the portion is directly on other elements, but also when other elements are interposed therebetween. When a portion such as a layer, a region, an element or the like is directly on other portions, no intervening elements may be therebetween.

In the present specification, when a layer, a region, a component, etc. are connected to each other, the layer, the region, and the components are directly connected to each other and/or the layer, the region, and the components may be indirectly connected to each other with other layers, other regions and other components interposed between the layer, the region, and the components. For example, when a layer, a region, a component, etc. are electrically connected to each other in the present specification, the layer, the region, the component, etc. are directly electrically connected to each other, and/or the layer, the region, the component, etc. are indirectly electrically connected to each other with other layers, other regions and other components interposed between the layer, the region, and the components.

In the present specification, the x-direction, the y-direction, and the z-direction are not limited to three axes on a Cartesian coordinate system, and may be interpreted in a broad sense including the same. For example, the x-direction, the y-direction, and the z-direction may be perpendicular to each other, but may refer to different directions that are not orthogonal to each other.

When it is called “plan view” herein, this means when you sees an object part from above (e.g., when looking in a direction perpendicular to an upper surface of a substrate), and when it is called “cross-sectional view”, this means when you see a cross-section in which the object part is cut vertically, from the side.

In the present specification, a first component that “overlaps” a second component means that the first component is disposed above or below the second component and at least a part of the first component overlaps the second component in a plan view.

In the present specification, in the case where some embodiments may be implemented in the present specification, a specific process order may be performed differently from the order described. For example, two processes described in succession may be substantially performed at the same time, or in an opposite order to an order to be described.

In the drawings, for convenience of explanation, the sizes of elements may be exaggerated or reduced. For example, since the size and thickness of each component shown in the drawings may be arbitrarily indicated for convenience of explanation, the disclosure is not necessarily limited to the illustration.

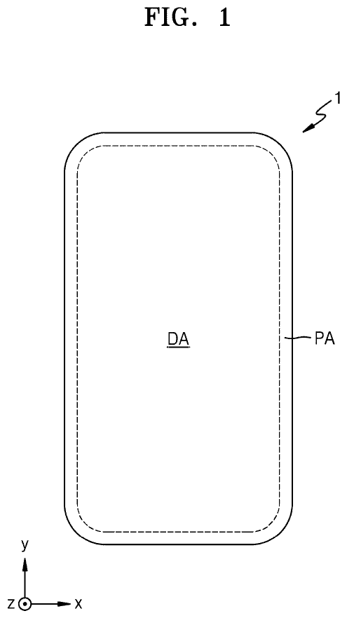

FIG. 1 is a plan view schematically illustrating a portion of a display apparatus according to an embodiment.

Referring to FIG. 1, a display apparatus 1 may include a display area DA, in which an image is displayed, and a peripheral area PA in a periphery of the display area DA (e.g., in a plan view). The display apparatus 1 may provide a certain image by using light emitted from a plurality of pixels arranged in the display area DA. In an embodiment, as shown in FIG. 1, the display area DA may have a rectangular shape in a plan view. However, embodiments of the present disclosure are not necessarily limited thereto, and the display area DA may have various shapes such as a polygonal shape, a circular shape, an elliptical shape or an amorphous shape, and the like (e.g., in a plan view).

The peripheral area PA may be an area in the periphery of the display area DA and may be a kind of non-display area in which a plurality of pixels are not arranged. In an embodiment, the display area DA may be entirely surrounded by the peripheral area PA (e.g., in the x and y directions). Various wirings for transmitting electrical signals to be applied to the display area DA, circuits, and pads to which a printed circuit board or a driver integrated circuit (IC) chip is attached may be located in the peripheral area PA.

A display apparatus according to embodiments of the present disclosure may be an apparatus for displaying at least one moving image and/or still image and may be used for a display screen of various products such as portable electronic devices, for example, a mobile phone, a smartphone, a tablet personal computer (PC), a mobile communication terminal, an electronic notebook, an electronic book, a portable multimedia player (PMP), a navigation system, and an ultra mobile PC (UMPC), televisions, laptop computers, monitors, billboards, Internet of Things (IoT) devices, and the like. However, embodiments of the present disclosure are not necessarily limited thereto. In addition, the display apparatus 1 according to an embodiment may be used for a wearable device such as a smart watch, a watch phone, a glasses type display, or a head mounted display (HMD). In addition, the display apparatus 1 according to an embodiment may be used as an instrument panel of a vehicle, and a center information display (CID) display disposed on a center fascia or a dashboard of a vehicle, a room mirror display for replacing a side mirror of a vehicle, and a display disposed on the rear surface of the front seat. In addition, the display apparatus 1 may be a flexible apparatus, a rollable apparatus, a foldable apparatus or a stretchable apparatus.

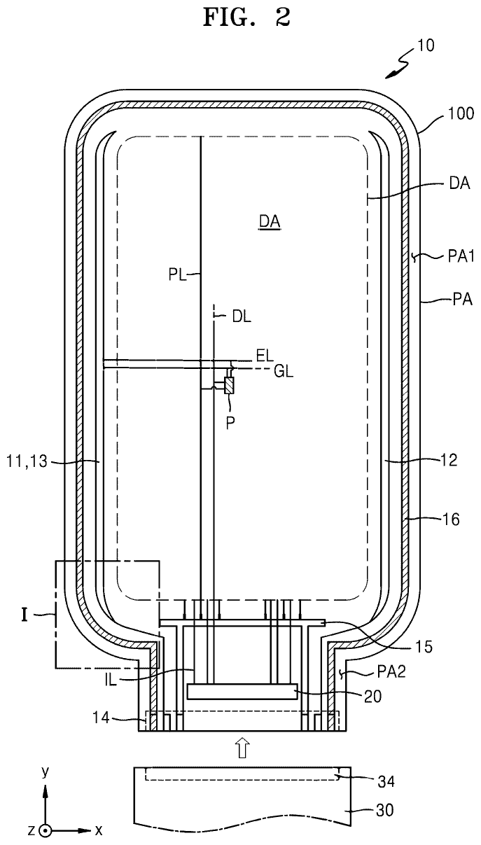

FIG. 2 is a plan view schematically illustrating a portion of a display apparatus according to an embodiment.

Referring to FIG. 2, the display apparatus may include a display panel 10 and a printed circuit board 30. The display panel 10 may include a substrate 100. Various components of the display panel 10 may be disposed on the substrate 100.

In an embodiment, the substrate 100 may include glass, metal, or a polymer resin. FIG. 2 illustrates that the display panel 10 is not bent and is in a flat state. However, in an embodiment, a portion of the display panel 10 may be bent and thus, the display panel 10 may be disposed on a rear surface of the substrate 100. When the display panel 10 is bent, the substrate 100 may have flexible or bendable characteristics.

In an embodiment, the substrate 100 may include a polymer resin, such as polyethersulfone, polyacrylate, polyether imide, polyethylene naphthalate, polyethylene terephthalate, polyphenylene sulfide, polyarylate, polyimide, polycarbonate, or cellulose acetate propionate. In an embodiment, various modifications are possible, such as the substrate 100 may have a multi-layered structure including two layers including a polymer resin and a barrier layer between the layers, wherein the barrier layer includes an inorganic material (e.g., silicon nitride, silicon oxide or silicon oxynitride, etc.).

A plurality of pixels P may be disposed in the display area DA. Each of the plurality of pixels P may be a sub-pixel, and may include a display element such as an organic light-emitting diode (OLED). In an embodiment, each pixel P may emit red, green, blue or white light, for example. However, embodiments of the present disclosure are not necessarily limited thereto.

The pixel P may be electrically connected to outer circuits disposed in the peripheral area PA. In an embodiment, a first scan driving circuit 11, a second scan driving circuit 12, an emission control driving circuit 13, a terminal 14, a first power supply wiring 15, a second power supply wiring 16, and a data driving circuit 20 may be arranged in the peripheral area PA.

Each of the first scan driving circuit 11 and the second scan driving circuit 12 may provide a scan signal to the pixel P through a gate signal line GL. The second scan driving circuit 12 may be arranged in parallel to the first scan driving circuit 11 (e.g., in the y direction) with the display area DA therebetween (e.g., in the x direction). A portion of the pixels P arranged in the display area DA may be electrically connected to the first scan driving circuit 11, and the other portion thereof may be connected to the second scan driving circuit 12. In some embodiments, the second scan driving circuit 12 may be omitted, and all the pixels P disposed in the display area DA may be electrically connected to the first scan driving circuit 11.

In an embodiment, the emission control driving circuit 13 may be arranged at the first scan driving circuit 11 and may provide an emission control signal to the pixels P through an emission control line EL. FIG. 2 illustrates that the emission control driving circuit 13 is disposed only in one side of the display area DA (e.g., the left side in the x-axis direction), however, in some embodiments the emission control driving circuit 13 may be disposed on both sides of the display area DA, similarly to the first scan driving circuit 11 and the second scan driving circuit 12.

The terminal 14 may be disposed in a second peripheral area PA2 of the substrate 100. In an embodiment, the terminal 14 may not be covered by an insulating layer and be exposed and may be electrically connected to the printed circuit board 30. A terminal 34 of the printed circuit board 30 may be electrically connected to the terminal 14 of the display panel 10.

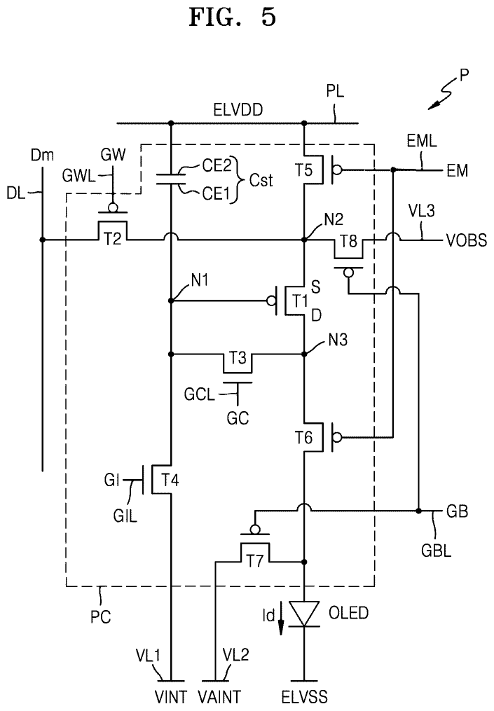

In an embodiment, the printed circuit board 30 may transmit a signal or power of a controller to the display panel 10. A control signal generated in the controller may be transmitted to each of driving circuits 11, 12, 13, and 20 through the printed circuit board 30. Also, the controller may transmit a driving voltage (see ELVDD of FIG. 5) to the first power supply wiring 15 and may provide a common voltage (see ELVSS of FIG. 5) to the second power supply wiring 16. The driving voltage ELVDD may be transmitted to each pixel P through the driving voltage line PL connected to the first power supply wiring 15, and the common voltage ELVSS may be transmitted to an opposite electrode of the pixel P connected to the second power supply wiring 16. The first power supply wiring 15 may have a shape in which it extends in one direction (e.g., an x-axis direction) from the lower side of the second area DA2. The second power supply wiring 16 may have a loop shape with an open side and may surround the display area DA partially.

The controller may generate a data signal (see Dm of FIG. 5), and the generated data signal Dm may be transmitted to an input line IL through the data driving circuit 20 and may be transmitted to the pixel P through the data line DL connected to the input line IL. FIG. 2 illustrates that the data driving circuit 20 is mounted in the second peripheral area PA2 of the substrate 100. However, embodiments of the present disclosure are not necessarily limited thereto. For example, in an embodiment, the data driving circuit 20 may be mounted on the printed circuit board 30.

In the specification, “line” may mean “wiring”. This is also applied to the following embodiments and modifications thereof.

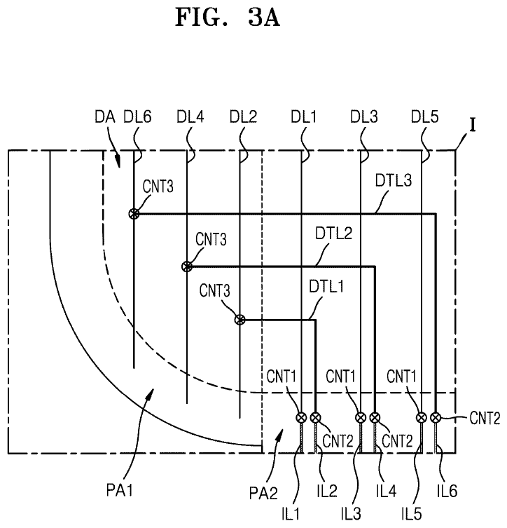

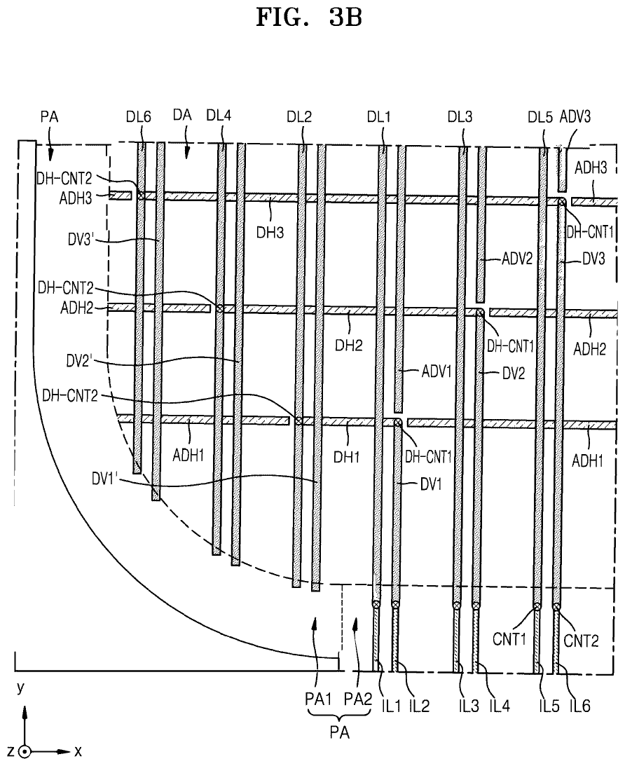

FIGS. 3A and 3B are respectively plan views schematically illustrating a portion of the display apparatus shown in FIG. 2. FIG. 3A is a schematic enlarged view of a region I of FIG. 2.

A plurality of pixels (see P of FIG. 2) may be arranged in the display area DA. A data signal (see Dm of FIG. 5) for controlling the brightness of each pixel P may be applied to the pixels P arranged in the display area DA.

Referring to FIGS. 3A and 3B, data lines DL1 to DL6, which are spaced apart from each other in a first direction (e.g., the x-axis direction) and extend in a second direction (e.g., the y-axis direction) crossing the first direction (x-axis direction) to be approximately in parallel to each other, may be arranged in the display area DA. In some embodiments, the data lines DL1 to DL6 may have a shape extending from the peripheral area PA to the inside of the display area DA, as shown in FIG. 3A. In an embodiment, in addition to the data lines DL1 to DL6, various wirings such as power lines and gate signal lines may also be located inside and outside the display area DA.

In an embodiment, the peripheral area PA may include a first peripheral area PA1 and a second peripheral area PA2. First through sixth input lines IL1 to IL6 may be arranged in the second peripheral area PA2. The first input line IL1 through the sixth input line IL6 may be connected to the data driving circuit (see 20 of FIG. 2) and may receive the data signal Dm. In an embodiment, the first data line DL1 through the sixth data line DL6 may be electrically connected to the first input line IL11 through the sixth input line IL6 and may transmit the data signal Dm to pixels in the display area DA.

FIGS. 3A and 3B illustrate six input lines and six data lines for convenience of explanation. However, embodiments of the present disclosure are not necessarily limited thereto, and the number of input lines and data lines may be greater than six in some embodiments.

The first input line IL1 through the sixth input line IL6 may be sequentially arranged in a center direction (e.g., the +x-axis direction) of the second peripheral area PA2 from an edge (e.g., adjacent to the first peripheral area PA1) of the second peripheral area PA2.

In an embodiment, the first input line IL1, the third input line IL3, and the fifth input line IL5, which are odd-numbered, may be electrically connected to the first data line DL1, the third data line DL3, and the fifth data line DL5, which are arranged adjacent to each other. As shown in FIGS. 3A and 3B, in an embodiment the first input line IL1, the third input line IL3, and the third input line IL5 may be electrically connected to the first data line DL1, the third data line DL3, and the fifth data line DL5, respectively, through a first contact hole CNT1. FIGS. 3A and 3B illustrate that the first contact hole CNT1 is disposed in the peripheral area PA. However, embodiments of the present disclosure are not necessarily limited thereto. For example, the first contact hole CNT1 may also be disposed in the display area DA in some embodiments.

In an embodiment, the first data line DL1, the third data line DL3, and the fifth data line DL5 may receive a data signal Dm from the first input line IL1, the third input line IL3, and the fifth input line IL5. In an embodiment, the first data line DL1, the third data line DL3, and the fifth data line DL5 may be arranged in a different layer from the first input line IL1, the third input line IL3, and the fifth input line IL5. In this embodiment, at least one insulating layer may be disposed between the first data line DL1, the third data line DL3, and the fifth data line DL5 and the first input line IL1, the third input line IL3, and the fifth input line IL5. However, embodiments of the present disclosure are not necessarily limited thereto. For example, in an embodiment, the first data line DL1, the third data line DL3, and the fifth data line DL5 may be arranged in the same layer as the first input line IL1, the third input line IL3, and the fifth input line IL5. Each of the first input line IL1, the third input line IL3, and the fifth input line IL5 may also be formed integrally to correspond to the first data line DL1, the third data line DL3, and the fifth data line DL5.

In an embodiment, the second input line IL2, the fourth input line IL4, and the sixth input line IL6, which are even-numbered, may be electrically connected to the adjacent second data line DL2, the fourth data line DL4, and the sixth data line DL6 through a first data transmission line DTL1, a second data transmission line DTL2, and a third data transmission line DTL3, as shown in FIG. 3A. The second data line DL2, the fourth data line DL4, and the sixth data line DL6 may receive a data signal from the second input line IL2, the fourth input line IL4, and the sixth input line IL6 through the first data transmission line DTL1, the second data transmission line DTL2, and the third data transmission line DTL3.

In an embodiment, the first data transmission line DTL1, the second data transmission line DTL2, and the third data transmission line DTL3 may be arranged to cross a portion of the display area DA, such as to pass through the display area DA. The second input line IL2 may be electrically connected to the second data line DL2 through the first data transmission line DTL1, the fourth input line IL4 may be electrically connected to the fourth data line through the second data transmission line DTL2, and the sixth input line IL6 may be electrically connected to the sixth data line DL6 through the third data transmission line DTL3.

In an embodiment, one end of each of the first data transmission line DTL1, the second data transmission line DTL2, and the third data transmission line DTL3 may be electrically connected to the second input line IL2, the fourth input line IL4, and the sixth input line IL6 through the second contact hole CNT2, and the other end of each of the first data transmission line DTL1, the second data transmission line DTL2, and the third data transmission line DTL3 may be electrically connected to the second data line DL2, the fourth data line DL4, and the sixth data line DL6 through the third contact hole CNT3. FIGS. 3A and 3B illustrate that the second contact hole CNT2 is disposed in the peripheral area PA. However, embodiments of the present disclosure are not necessarily limited thereto. For example, the second contact hole CNT2 may also be disposed in the display area DA. The third contact hole CNT3 may also be disposed in the display area DA.

However, embodiments of the present disclosure are not necessarily limited thereto. For example, in an embodiment, the first data transmission line DTL1, the second data transmission line DTL2, and the third data transmission line DTL3 may be arranged in the same layer as the second input line IL2, the fourth input line IL4, and the sixth input line IL6. Each of the first data transmission line DTL1, the second data transmission line DTL2, and the third data transmission line DTL3 may be integrally formed to correspond to the second input line IL2, the fourth input line IL4, and the sixth input line IL6.

Through the structure, the second input line IL2 may be configured to transmit a data signal to the second data line DL2, the fourth input line IL4 may be configured to transmit a data signal to the fourth data line DL4, and the sixth input line IL6 may be configured to transmit a data signal to the sixth data line DL6.

FIG. 3B illustrates the configuration of the first data transmission line DTL1, the second data transmission line DTL2, and the third data transmission line DTL3 of FIG. 3A in detail.

As described with reference to FIG. 3A, the second input line IL2, the fourth input line IL4, and the sixth input line IL6 may be electrically connected to the second data line DL2, the fourth data line DL4, and the sixth data line DL6 through the first data transmission line DTL1, the second data transmission line DTL2, and the third data transmission line DTL3. In this embodiment, the first data transmission line DTL1 may include a first vertical connection line DV1 and a first horizontal connection line DH1. Similarly, the second data transmission line DTL2 may include a second vertical connection line DV2 and a second horizontal connection line DH2. The third data transmission line DTL3 may include a third vertical connection line DV3 and a third horizontal connection line DH3.

The first vertical connection line DV1, the second vertical connection line DV2, and the third vertical connection line DV3 may be arranged approximately in parallel to the first data line DL1 through the sixth data line DL6. In an embodiment, the first horizontal connection line DH1, the second horizontal connection line DH2, and the third horizontal connection line DH3 may extend in a first direction (e.g., the x-axis direction) crossing a second direction (e.g., the y-axis direction) in which the first data line DL1 through the sixth data line DL6 extend.

In an embodiment, each of the second input line IL2, the fourth input line IL4, and the sixth input line IL6 may be electrically connected to correspond to the first vertical connection line DV1, the second vertical connection line DV2, and the third vertical connection line DV3 through the second contact hole CNT2. In an embodiment, each of the first horizontal connection line DH1, the second horizontal connection line DH2, and the third horizontal connection line DH3 may be electrically connected to correspond to the first vertical connection line DV1, the second vertical connection line DV2, and the third vertical connection line DV3 through the first connection contact hole DH-CNT1 located at one end of each of the first horizontal connection line DH1, the second horizontal connection line DH2, and the third horizontal connection line DH3. Each of the first horizontal connection line DH1, the second horizontal connection line DH2, and the third horizontal connection line DH3 may be electrically connected to correspond to the second data line DL2, the fourth data line DL4, and the sixth data line DL6 through the second connection contact hole DH-CNT2 located at the other end of each of the first horizontal connection line DH1, the second horizontal connection line DH2, and the third horizontal connection line DH3. The second connection contact hole DH-CNT2 may be the third contact hole CNT3 of FIG. 3A.

In an embodiment, a first additional vertical connection line DV1′, a second additional vertical connection line DV2′, and a third additional connection line DV3′ may be arranged approximately in parallel to the second data line DL2, the fourth data line DL4, and the sixth data line DL6 (e.g., in the y-axis direction). The first additional vertical connection line DV1′, the second additional vertical connection line DV2′, and the third additional vertical connection line DV3′ may be configured to reduce a structural difference in pixels in which the first vertical connection line DV1, the second vertical connection line DV2 and the third vertical connection line DV3 pass, and pixels in which the first vertical connection line DV1, the second vertical connection line DV2 and the third vertical connection line DV3 do not pass. Thus, a display apparatus that may display high-quality images by reducing brightness deviation between pixels, may be implemented.

In an embodiment, the first data line DL1 through the sixth data line DL6, the first vertical connection line DV1 through the third vertical connection line DV3, and the first additional vertical connection line DV1′ through the third additional vertical connection line DV3′ may be located in the same layer. The first horizontal connection line DH1 through the third horizontal connection line DH3 may be located in a different layer from the first data line DL1 through the sixth data line DL6. In some embodiments, certain components that are located in the same layer may mean that the components are simultaneously formed of the same material through the same mask process. In this embodiment, the components include materials having the same layer structure and the same property or the like.

When viewed in a direction (e.g., the z-axis direction) perpendicular to the substrate 100, the first horizontal connection line DH1 may cross the first data line DL1, the second horizontal connection line DH2 may cross the first data line DL1 through the third data line DL3, and the third horizontal connection line DH3 may cross the first data line DL1 through the fifth data line DL5. Thus, to prevent the first horizontal connection line DH1 to the third horizontal connection line DH3 from contacting intersecting data lines, the first horizontal connection line DH1, the second horizontal connection line DH2, and the third horizontal connection line DH3 may be located below the first data line DL1 to the sixth data line DL6 as described above.

As shown in FIG. 3B, the display apparatus according to an embodiment may further include dummy wirings.

For example, the display apparatus may include a first auxiliary horizontal connection line ADH1 that is spaced apart from the first horizontal connection line DH1 (e.g., in the x-axis direction), is electrically insulated from the first horizontal connection line DH1 and the second data line DL2 and has the same extension axis as an extension axis of the first horizontal connection line DH1. For example, in an embodiment the display apparatus may include a first auxiliary horizontal connection line ADH1 located at one side (e.g., the −x-axis direction) of the first horizontal connection line DH1, and a first auxiliary horizontal connection line ADH1 located at the other side (e.g., the +x-axis direction) of the first horizontal connection line DH1. Similarly, the display apparatus may include a second auxiliary horizontal connection line ADH2 located at one side (e.g., the −x-axis direction) of the second horizontal connection line DH2 and a second auxiliary horizontal connection line ADH2 located at the other side (e.g., the +x-axis direction) of the second horizontal connection line DH2, a third auxiliary horizontal connection line ADH3 located at one side (e.g., the −x-axis direction) of the third horizontal connection line DH3, and a third auxiliary horizontal connection line ADH3 located at the other side (e.g., the +x-axis direction) of the third horizontal connection line DH3.

Accordingly, structural differences between pixels passing through the first horizontal connection line DH1 to the third horizontal connection line DH3 and pixels passing through the first horizontal connection line DH1 to the third horizontal connection line DH3 may be reduced. As a result, a display apparatus capable of displaying high-quality images by reducing the difference in brightness implemented in pixels when the same electrical signal is applied to the pixels, may be implemented. In an embodiment, the first auxiliary horizontal connection line ADH1 through the third auxiliary horizontal connection line ADH3 and the first horizontal connection line DH1 through the third horizontal connection line DH3 may be disposed in the same layer.

Similarly, the display apparatus according to an embodiment may include a first auxiliary vertical connection line ADV1 that is spaced apart from the first vertical connection line DV1 (e.g., in the y-axis-direction), is electrically insulated from the first vertical connection line DV1 and the first horizontal connection line DH1, has the same extension axis as an extension axis of the first vertical connection line DV1 and is located at one side (e.g., the +y-axis direction) of the first vertical connection line DV1. Similarly, the display apparatus may include a second auxiliary vertical connection line ADV2 located at one side (e.g., the +y direction) of the second vertical connection line, and a third auxiliary vertical connection line ADV3 located at one side (e.g., the +y direction) of the third vertical connection line DV3. The first auxiliary vertical connection line ADV1 through the third auxiliary vertical connection line ADV3 and the first vertical connection line DV1 through the third vertical connection line DV3 may be disposed in the same layer.

To this end, the first auxiliary vertical connection line ADV1, the second auxiliary vertical connection line ADV2, and the third auxiliary vertical connection line ADV3 may reduce a structural difference in pixels in which the first vertical connection line DV1 through the third vertical connection line DV3 pass, and pixels in which the first vertical connection line DV1 through the third vertical connection line DV3 do not pass. Thus, a display apparatus in which a brightness deviation between pixels may be reduced so that high-quality images may be displayed, may be implemented.

In an embodiment, the first additional vertical connection line DV1′ through the third additional vertical connection line DV3′, the first auxiliary horizontal connection line ADH1 through the third auxiliary horizontal connection line ADH3, and the first auxiliary vertical connection line ADV1 through the third auxiliary vertical connection line ADV3 may be configured to transmit a constant voltage (e.g., a common voltage ELVSS). The first additional vertical connection line DV1′ through the third additional vertical connection line DV3′, the first auxiliary horizontal connection line ADH1 through the third auxiliary horizontal connection line ADH3, and the first auxiliary vertical connection line ADV1 through the third auxiliary vertical connection line ADV3 may be electrically connected to each other and may constitute a constant voltage mesh structure.

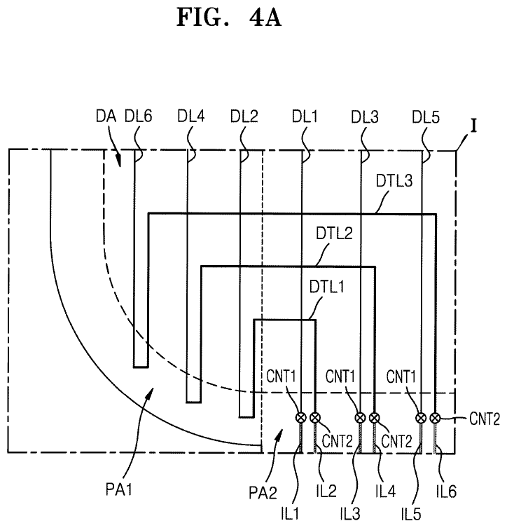

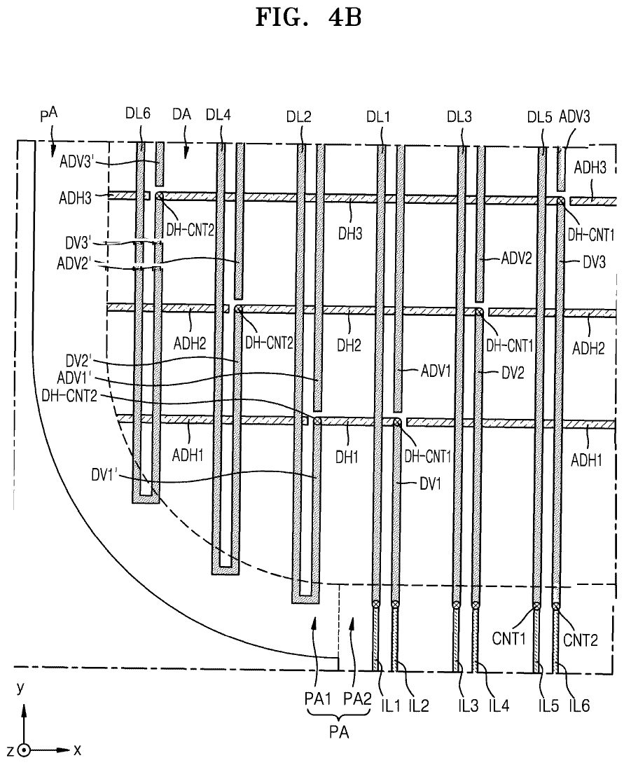

FIGS. 4A and 4B are respectively plan views schematically illustrating a portion of the display apparatus shown in FIG. 2.

FIG. 4A is similar to FIG. 3A, however, there is a difference in that each of the first data transmission line DTL1, the second data transmission line DTL2 and the third data transmission line DTL3 is connected to the second data line DL2, the fourth data line DL4 and the sixth data line DL6 in the first peripheral area PA1.

Referring to FIG. 4A, the first input line IL1 through the sixth input line IL6 may be sequentially arranged in a center direction (e.g., the +x-axis direction) of the second peripheral area PA2 from an edge (adjacent to the first peripheral area PA1) of the second peripheral area PA2.

In an embodiment, the first input line IL1, the third input line IL3, and the fifth input line IL5, which are odd-numbered, may be electrically connected to the first data line DL1, the third data line DL3, and the fifth data line DL5, which are arranged adjacent to each other. In an embodiment, each of the first input line IL1, the third input line IL3, and the fifth input line IL5 may be electrically connected to correspond to the first data line DL1, the third data line DL3, and the fifth data line DL5 through the first contact hole CNT1.

In an embodiment, the second input line IL2, the fourth input line IL4, and the sixth input line IL6, which are even-numbered, may be electrically connected to the adjacent second data line DL2, the fourth data line DL4, and the sixth data line DL6 through the first data transmission line DTL1, the second data transmission line DTL2, and the third data transmission line DTL3. One end of each of the first data transmission line DTL1, the second data transmission line DTL2, and the third data transmission line DTL3 may be electrically connected to the second input line IL2, the fourth input line IL4, and the sixth input line IL6 through the second contact hole CNT2, and the other end of each of the first data transmission line DTL1, the second data transmission line DTL2, and the third data transmission line DTL3 may be electrically connected to the second data line DL2, the fourth data line DL4, and the sixth data line DL6 in the first peripheral area PA1.

FIG. 4B illustrates the configuration of the first data transmission line DTL1, the second data transmission line DTL2, and the third data transmission line DTL3 of FIG. 4A in detail.

As described with reference to FIG. 4A, in an embodiment the second input line IL2, the fourth input line IL4, and the sixth input line IL6 may be electrically connected to the second data line DL2, the fourth data line DL4, and the sixth data line DL6 through the first data transmission line DTL1, the second data transmission line DTL2, and the third data transmission line DTL3. In this embodiment, the first data transmission line DTL1 may include a first vertical connection line DV1, a first horizontal connection line DH1, and a first additional vertical connection line DV1′. Similarly, the second data transmission line DTL2 may include a second vertical connection line DV2, a second horizontal connection line DH2, and a second additional vertical connection line DV2′. The third data transmission line DTL3 may include a third vertical connection line DV3, a third horizontal connection line DH3, and a third additional vertical connection line DV3′.

In an embodiment, the first vertical connection line DV1 through the third vertical connection line DV3 and the first additional vertical connection line DV1′ through the third additional vertical connection line DV3′ may extend in a second direction (e.g., the y-axis direction) and may be arranged approximately in parallel to the first data line DL1 through the sixth data line DL6. The first horizontal connection line DH1 through the third horizontal connection line DH3 may extend in the first direction (e.g., the x-axis direction).

In an embodiment, each of the second input line IL2, the fourth input line IL4, and the sixth input line IL6 may be electrically connected to correspond to the first vertical connection line DV1, the second vertical connection line DV2, and the third vertical connection line DV3 through the second contact hole CNT2. Each of the first horizontal connection line DH1, the second horizontal connection line DH2, and the third horizontal connection line DH3 may be electrically connected to correspond to the first vertical connection line DV1, the second vertical connection line DV2, and the third vertical connection line DV3 through the first connection contact hole DH-CNT1 located at one end of each of the first horizontal connection line DH1, the second horizontal connection line DH2, and the third horizontal connection line DH3. Each of the first horizontal connection line DH1, the second horizontal connection line DH2, and the third horizontal connection line DH3 may be electrically connected to correspond to the first additional vertical connection line DV1′, the second additional vertical connection line DV2′, and the third additional vertical connection line DV3′ through the second connection contact hole DH-CNT2 located at the other end of each of the first horizontal connection line DH1, the second horizontal connection line DH2, and the third horizontal connection line DH3. Each of the first additional vertical connection line DV1′, the second additional vertical connection line DV2′, and the third additional vertical connection line DV3′ may be integrally formed to correspond to the second data line DL2, the fourth data line DL4, and the sixth data line DL6.

In an embodiment, the first data line DL1 through the sixth data line DL6, the first vertical connection line DV1 through the third vertical connection line DV3, and the first additional vertical connection line DV1′ through the third additional vertical connection line DV3′ may be located in the same layer. The first horizontal connection line DH1 through the third horizontal connection line DH3 may be located in a different layer from the first data line DL1 through the sixth data line DL6.

In an embodiment, the display apparatus may include a first auxiliary horizontal connection line ADH1 that is spaced apart from the first horizontal connection line DH1 (e.g., in the x-axis direction), is electrically insulated from the first horizontal connection line DH1 and the second data line DL2 and has the same extension axis as an extension axis of the first horizontal connection line DH1. The display apparatus may include a first auxiliary horizontal connection line ADH1 located at one side (e.g., the −x-axis direction) of the first horizontal connection line DH1, and a first auxiliary horizontal connection line ADH1 located at the other side (e.g., the +x-axis direction). Similarly, the display apparatus may include a second auxiliary horizontal connection line ADH2 located at one side (e.g., the −x-axis direction) of the second horizontal connection line DH2 and a second auxiliary horizontal connection line ADH2 located at the other side (e.g., the +x direction) of the second horizontal connection line DH2, a third auxiliary horizontal connection line ADH3 located at one side (e.g., the −x-axis direction) of the third horizontal connection line DH3, and a third auxiliary horizontal connection line ADH3 located at the other side (e.g., the +x-axis direction) of the third horizontal connection line DH3. The first auxiliary horizontal connection line ADH1 through the third auxiliary horizontal connection line ADH3 and the first horizontal connection line DH1 through the third horizontal connection line DH3 may be disposed in the same layer.

Similarly, the display apparatus according to an embodiment of the present disclosure may include a first auxiliary additional vertical connection line ADV1′ that is spaced apart from the first additional vertical connection line DV1′ (e.g., in the y-axis direction), is electrically insulated from the first additional vertical connection line DV1′ and the first horizontal connection line DHI1, has the same extension axis as an extension axis of the first additional vertical connection line DV1′ and is located at one side (e.g., the +y-axis direction) of the first additional vertical connection line DV1′. Similarly, the display apparatus may include a second auxiliary additional vertical connection line ADV2′ located at one side (e.g., the +y-axis direction) of the second additional vertical connection line DV2′, and a third auxiliary additional vertical connection line ADV3′ located at one side (e.g., the +y-axis direction) of the third additional vertical connection line DV3′. The first auxiliary additional vertical connection line ADV1′ through the third auxiliary additional vertical connection line ADV3′ and the first additional vertical connection line DV1′ through the third additional vertical connection line DV3′ may be disposed in the same layer.

In addition, the display apparatus may include a first auxiliary vertical connection line ADV1 that is spaced apart from the first vertical connection line DV1 (e.g., in the y-axis direction), is electrically insulated from the first vertical connection line DV1 and the first horizontal connection line DH1, has the same extension axis as an extension axis of the first vertical connection line DV1 and is located at one side (e.g., the +y-axis direction) of the first vertical connection line DV1. Similarly, the display apparatus may include a second auxiliary vertical connection line ADV2 located at one side (e.g., the +y-axis direction) of the second vertical connection line, and a third auxiliary vertical connection line ADV3 located at one side (e.g., the +y-axis direction) of the third vertical connection line DV3. The first auxiliary vertical connection line ADV1 through the third auxiliary vertical connection line ADV3 and the first vertical connection line DV1 through the third vertical connection line DV3 may be disposed in the same layer.

In an embodiment, the first additional vertical connection line ADV1′ through the third additional vertical connection line ADV3′, the first auxiliary horizontal connection line ADH1 through the third auxiliary horizontal connection line ADH3, and the first auxiliary vertical connection line ADV1 through the third auxiliary vertical connection line ADV3 may be configured to transmit a constant voltage (e.g., a common voltage ELVSS). In an embodiment, the first auxiliary additional vertical connection line ADV1′ through the third auxiliary additional vertical connection line ADV3′, the first auxiliary horizontal connection line ADH1 through the third auxiliary horizontal connection line ADH3, and the first auxiliary vertical connection line ADV1 through the third auxiliary vertical connection line ADV3 may be electrically connected to each other and may constitute a constant voltage mesh structure.

FIG. 5 is an equivalent circuit diagram of one pixel of a display apparatus according to an embodiment.

Referring to FIG. 5, one pixel P may include an organic light-emitting diode OLED and a pixel circuit PC electrically connected to the organic light-emitting diode OLED. In an embodiment, the pixel circuit PC may include first through eighth transistors T1 through T8 and a storage capacitor Cst. The first transistor T1 may be a driving transistor that outputs a driving current corresponding to a data signal Dm, and the second through eighth transistors T2 to T8 may be switching transistors for transmitting signals.

A first terminal (e.g., a first electrode) of each of first through eighth transistors T1 through T8 may be a source or drain, and a second terminal (e.g., a second electrode) thereof may be a terminal different from the first terminal. For example, in an embodiment in which the first terminal is a drain, the second terminal may be a source.

A node to which a gate of the first transistor T1 is connected (e.g., electrically connected thereto), may be defined as a first node N1, a node to which a first terminal S of the first transistor T1 is connected (e.g., electrically connected thereto), may be defined as a second node N2, and a node to which a second terminal D of the first transistor T1 may be defined as a third node N3.

In an embodiment, the pixel circuit PC of each pixel P may be connected to (e.g., electrically connected thereto) a first gate signal line GWL for transmitting a first gate signal GW, a second gate signal line GIL for transmitting a second gate signal GI, a third gate signal line GCL for transmitting a third gate signal GC, a fourth gate signal line GBL for transmitting a fourth gate signal GB, an emission control signal line EML for transmitting an emission control signal EM, a data line DL for transmitting a data signal Dm, a driving voltage line PL for transmitting a driving voltage ELVDD, a first initialization voltage line VL1 for transmitting a first initialization voltage VNT, a second initialization voltage line VL2 for transmitting a second initialization voltage VAINT, and an on-bias voltage VL3 for transmitting an on-bias voltage VOBS.

In an embodiment, a first transistor T1 may include a gate (e.g., a gate electrode) connected to (e.g., electrically connected thereto) the first node N1, a first terminal S connected to (e.g., electrically connected thereto) the second node N2, and a second terminal D connected to (e.g., electrically connected thereto) the third node N3. The first terminal S of the first transistor T1 may be connected to (e.g., electrically connected thereto) the driving voltage line PL via the fifth transistor T5, and the second terminal D of the first transistor T1 may be connected to (e.g., electrically connected thereto) a pixel electrode (e.g., an anode) of the organic light-emitting diode OLED via the sixth transistor T6. The first transistor T1 may control the amount of a driving current flowing through the pixel electrode of the organic light-emitting diode OLED by receiving the data signal Dm according to a switching operation of the second transistor T2.

The second transistor T2 may be connected between the data line DL and the first transistor T1. In an embodiment, the second transistor T2 may include a gate connected to (e.g., electrically connected thereto) the first gate signal line GWL, a first terminal connected to (e.g., electrically connected thereto) the data line DL, and a second terminal connected to (e.g., electrically connected thereto) the second node N2. The second transistor T2 may be turned on by the first gate signal GW transmitted to the first gate line GWL, may be configured to electrically connect the data line DL to the second node N2 and may transmit the data signal Dm to the second node N2 from the data signal line DL.

The third transistor T3 may be connected between the gate of the first transistor T1 and the first terminal S of the first transistor T1. In an embodiment, the third transistor T3 may include a gate connected to (e.g., electrically connected thereto) the third gate signal line GCL, a first terminal connected to (e.g., electrically connected thereto) the first node N1, and a second terminal connected to (e.g., electrically connected thereto) the third node N3. The third transistor T3 may be turned on by the third gate signal GC transmitted to the third gate signal line GCL, thereby diode-connecting the first node N1 and the third node N3 to each other.

The fourth transistor T4 may be connected between the first initialization voltage line VL1 and a gate of the first transistor T1. In an embodiment, the fourth transistor T4 may include a gate connected to (e.g., electrically connected thereto) the second gate line GIL, a first terminal connected to (e.g., electrically connected thereto) the first node N1, and a second terminal connected to (e.g., electrically connected thereto) the first initialization voltage line VL1. The fourth transistor T4 may be turned on by the second gate signal GI transmitted to the second gate line GIL and may transmit the first initialization voltage VINT to the first node N1 from the first initialization voltage line VL1.

The fifth transistor T5 may be connected between the driving voltage line PL and the first transistor T′. In an embodiment, the fifth transistor T5 may include a gate connected to (e.g., electrically connected thereto) the emission control signal line EML, a first terminal connected to (e.g., electrically connected thereto) the driving voltage line PL, and a second terminal connected to (e.g., electrically connected thereto) the second node N2.

The sixth transistor T6 may be connected between the first transistor T1 and the organic light-emitting diode OLED. In an embodiment, the sixth transistor T6 may include a gate connected to (e.g., electrically connected thereto) the emission control line EL, a first terminal connected to (e.g., electrically connected thereto) the third node N3, and a second terminal connected to (e.g., electrically connected thereto) a pixel electrode of the organic light-emitting diode OLED. In an embodiment, the fifth transistor T5 and the sixth transistor T6 may be simultaneously turned on by the emission control signal EM transmitted to the emission control signal line EML so that a driving current Id may flow through the pixel electrode of the organic light-emitting diode OLED.

The seventh transistor T7 may be connected between the second initialization voltage line VL2 and the organic light-emitting diode OLED. In an embodiment, the seventh transistor T7 may include a gate connected to (e.g., electrically connected thereto) the fourth gate signal line GBL, a first terminal connected to (e.g., electrically connected thereto) the second initialization voltage line VL2, and a second terminal connected to (e.g., electrically connected thereto) the pixel electrode of the organic light-emitting diode OLED. In an embodiment, the seventh transistor T7 may be turned on by the fourth gate signal GB transmitted to the fourth gate signal line GBL and may transmit the second initialization voltage VAINT to the pixel electrode of the organic light-emitting diode OLED from the second initialization voltage line VL2.

The eighth transistor T8 may be connected between the on-bias voltage line VL3 and the first transistor T1. In an embodiment, the eighth transistor T8 may include a gate connected to (e.g., electrically connected thereto) the fourth gate signal line GBL, a first terminal connected to (e.g., electrically connected thereto) the second node N2, and a second terminal connected to (e.g., electrically connected thereto) the on-bias voltage line VL3. In an embodiment, the seventh transistor T8 may be turned on by the fourth gate signal GB transmitted to the fourth gate signal line GBL and may transmit the on-bias voltage VOBS to the second node N2 from the on-bias voltage line VL3.

In an embodiment, the display apparatus may support a variable refresh rate (VRR). The refresh rate is a frequency at which a data signal Dm is substantially written to the first transistor T1 of a pixel P, and may represent a screen scanning rate, a screen refresh rate, and the number of image frames played for one second. One frame may include an address scan period and a self-scan period according to a refresh rate. In an embodiment in which the display apparatus is driven with a low refresh rate, an on-bias voltage VOBS may be applied to the second node N2 for a self scan period so that the first transistor T1 may be prevented from being deteriorated.

The storage capacitor Cst may be connected between the driving voltage line PL and a gate of the first transistor T1. In an embodiment, the first capacitor electrode CE1 of the storage capacitor Cst may be connected to (e.g., electrically connected thereto) the first node N1, and the second capacitor electrode CE2 may be connected to (e.g., electrically connected thereto) the driving voltage line PL. The storage capacitor Cst may store a threshold voltage of the first transistor T1 and a voltage corresponding to the data signal Dm.

The organic light-emitting diode OLED may include a pixel electrode (e.g., an anode), an opposite electrode (e.g., a cathode) facing the pixel electrode, and an intermediate layer between the pixel electrode and the opposite electrode. In an embodiment, the opposite electrode may receive a common voltage ELVSS, and may be a common electrode that is common in the plurality of pixels P. However, embodiments of the present disclosure are not necessarily limited thereto.

A portion of the first through eighth transistors T1 through T8 may be a P-channel transistor, and the other portion thereof may be an N-channel transistor. In an embodiment, the first transistor T1, the second transistor T2, and the fifth through eighth transistors T5 through T8 may be P-channel transistors, and the third transistor T3 and the fourth transistor T4 may be N-channel transistors. However, embodiments of the present disclosure are not necessarily limited thereto. For example, in some embodiments, all of the first through eighth transistors T1 through T8 may be N-channel transistors, or P-channel transistors.

In an embodiment, some transistors included in the pixel circuit PC may be oxide thin-film transistors, and the other transistors may be silicon thin-film transistors. The oxide thin-film transistor may be a low temperature polycrystalline oxide (LTPO) thin-film transistor in which an active pattern (e.g., a semiconductor layer) includes an oxide. The silicon thin-film transistor may be a low temperature poly-silicon (LTPS) thin-film transistor in which the active pattern (e.g., a semiconductor layer) includes amorphous silicon and polysilicon etc.

FIG. 5 illustrates that the pixel circuit PC includes first through eighth transistors T1 through T8 and a storage capacitor Cst. However, embodiments of the present disclosure are not necessarily limited thereto. For example, some of the transistors and capacitors may be omitted or additional transistors and capacitors may be added in some embodiments.

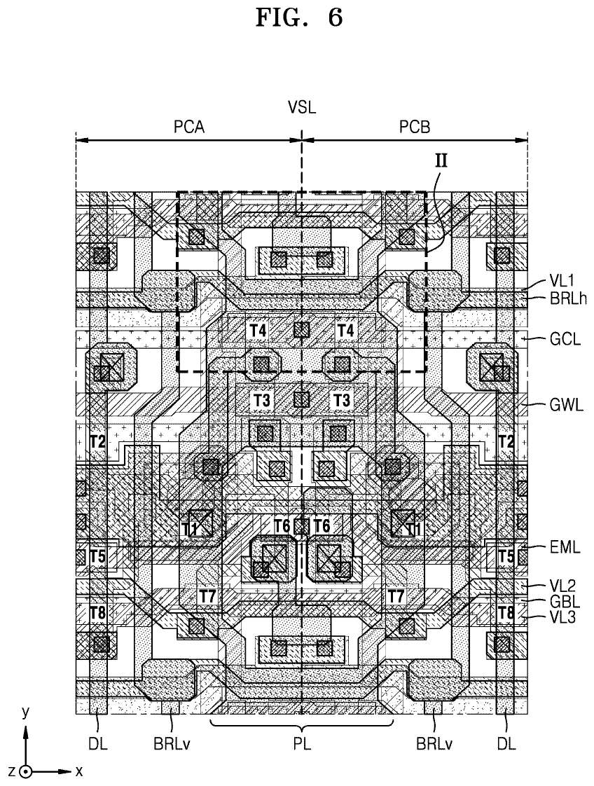

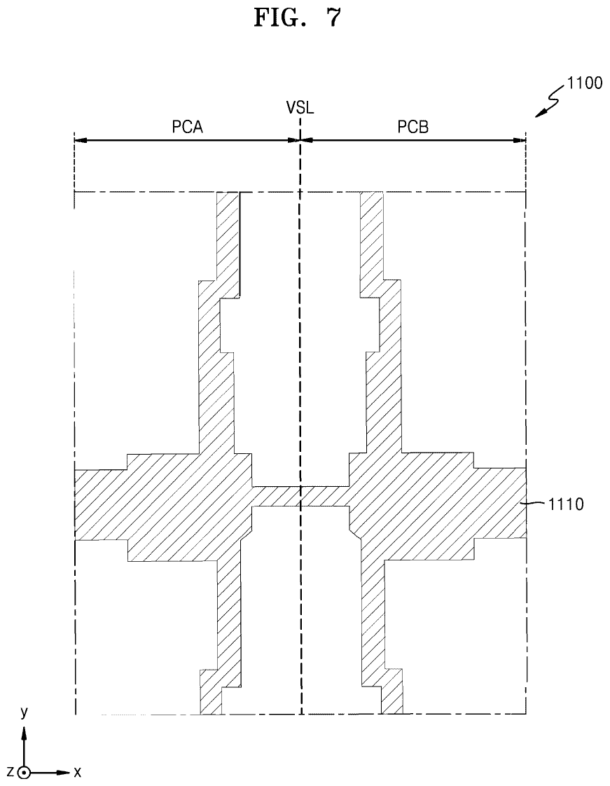

FIG. 6 is an arrangement view schematically illustrating a portion of a display apparatus according to an embodiment, and FIGS. 7 through 13 are respectively arrangement views schematically illustrating a portion of the display apparatus shown in FIG. 6 according to layers.

Referring to FIG. 6, a display area (see DA of FIG. 1) may include a plurality of pixel areas PCA and PCB in which the pixel circuit (see PC of FIG. 5) is arranged. In two first pixel areas PCA and the second pixel area PCB adjacent to each other in the first direction (e.g., the x-axis direction), pixel circuits PCs linearly symmetrical to the virtual straight line VSL extending in the second direction (e.g., the y-axis direction) may be disposed. The components of the pixel circuit PC arranged in the first pixel area PCA may be linearly symmetrical to components of the pixel circuit PC arranged in the second pixel area PCB, unless otherwise stated. For convenience of illustration, an identification number is assigned to only one of the symmetrical components. Hereinafter, this will be described with reference to FIGS. 6 through 13 together.

The first conductive layer 1100 may be arranged on a substrate (see 100 of FIG. 2). In an embodiment, the first conductive layer 1100 may include a conductive material including molybdenum (Mo), aluminum (Al), copper (Cu), titanium (Ti), or the like, and may have a multi-layered or single layer structure including the materials described above.

Referring to FIG. 7, the first conductive layer 1100 may include a first conductive pattern 1110. The first conductive pattern 1110 may include a first connection portion extending longitudinally in the first direction (e.g., the x-axis direction), a second connection portion extending longitudinally in the second direction (e.g. the y-axis direction), and a body portion. The body portion of the first conductive pattern 1110 may overlap the channel region A1 of the first transistor T1 (e.g., in the z-axis direction) so that the first transistor T1 may be prevented from being deteriorated by external light etc.

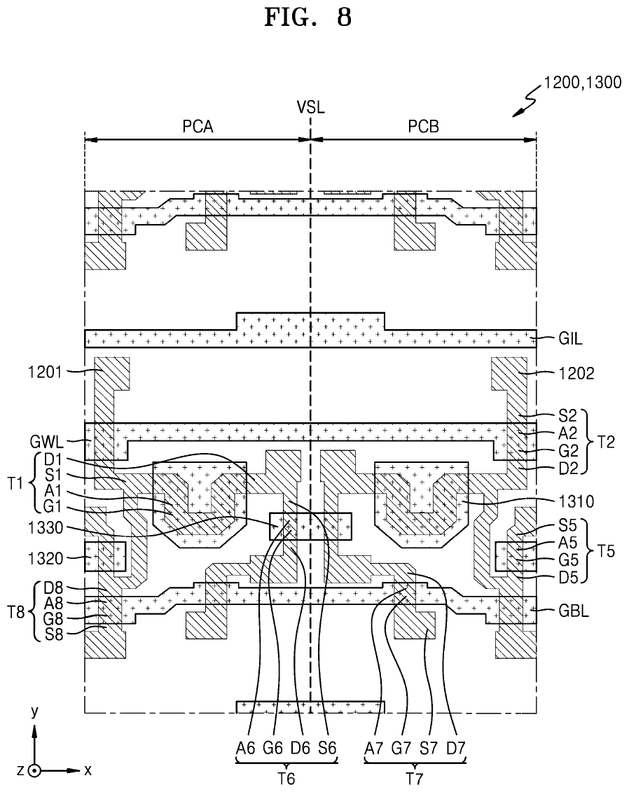

For convenience of description, FIG. 8 shows the first semiconductor layer 1200 and the second conductive layer 1300 overlapping each other (e.g., in the z-axis direction). Referring to FIG. 8, a first semiconductor layer 1200 may be disposed on the first conductive layer 1100, and a second conductive layer 1300 may be disposed on the first semiconductor layer 1200. In an embodiment, at least one insulating layer may be disposed between the first conductive layer 1100 and the first semiconductor layer 1200 and between the first semiconductor layer 1200 and the second conductive layer 1300, respectively (e.g., in the z-axis direction).

In an embodiment, the first semiconductor layer 1200 may include a silicon-based semiconductor material, for example, amorphous silicon or polysilicon. The second conductive layer 1300 may include a conductive material including Mo, Al, Cu, Ti, or the like, and may have a multi-layered or single layer structure including the materials described above. However, embodiments of the present disclosure are not necessarily limited thereto.

In an embodiment, the first semiconductor layer 1200 may include a first semiconductor pattern 1201 and a second semiconductor pattern 1202 that are linearly symmetrical with respect to the virtual straight line VSL. Each of the first semiconductor pattern 1201 and the second semiconductor pattern 1202 may include a channel region A1 of the first transistor T1, a channel region A2 of the second transistor T2, a channel region A5 of the fifth transistor T5, a channel region A6 of the sixth transistor T6, a channel region A7 of the seventh transistor T7, and a channel region A8 of the eighth transistor T8. A source region and a drain region may be disposed on both sides of each of the channel regions A1, A2, A5, A6, A7, and A8.

In an embodiment, the second conductive layer 1300 may include a second conductive pattern 1310, a third conductive pattern 1320, a fourth conductive pattern 1330, a first gate signal line GWL, a second gate signal line GIL, and a fourth gate signal line GBL. In an embodiment, the second through fourth conductive patterns 1310, 1320, and 1330 may have island-type configurations. Each of the first gate signal line GWL, the second gate signal line GIL, and the fourth gate signal line GBL may extend longitudinally substantially in the first direction (e.g., the x-axis direction). The first gate signal line GWL may be configured to transmit a first gate signal (see GW of FIG. 5) to pixel circuits arranged in the same pixel row, the second gate signal line GIL may be configured to transmit a second gate signal (see GI of FIG. 5) to pixel circuits arranged in the same pixel row, and the fourth gate signal line GBL may be configured to transmit a fourth gate signal (see GB of FIG. 5) to pixel circuits arranged in the same pixel row.

In an embodiment, the channel region A1 of the first transistor T1 may overlap the second conductive pattern 1310 (e.g., in the z-axis direction) and may have a bent shape. The second conductive pattern 1310 may be a gate electrode G1 of the first transistor T1. A source region S1 and a drain region D1 may be arranged on both sides of the channel region A1 of the first transistor T1.

A channel region A2 of the second transistor T2 may overlap the first gate signal line GWL (e.g., in the z-axis direction). A part of the first gate signal line GWL that overlaps the channel region A2 of the second transistor T2 may be the gate electrode G2 of the second transistor T2. A source region S2 and a drain region D2 may be arranged on both sides of the channel region A2 of the second transistor T2. The drain region D2 of the second transistor T2 may be connected to the source region S1 of the first transistor T1.

A channel region A5 of the fifth transistor T5 may overlap a third conductive pattern 1320 (e.g., in the z-axis direction). The third conductive pattern 1320 may be a gate electrode G5 of the fifth transistor T5. A source region S5 and a drain region D5 may be arranged on both sides of the channel region A5 of the fifth transistor T5. The drain region D5 of the fifth transistor T5 may be connected to the source region S1 of the first transistor T1.

A channel region A6 of the sixth transistor T6 may overlap a fourth conductive pattern 1330 (e.g., in the z-axis direction). The fourth conductive pattern 1330 may be a gate electrode G6 of the sixth transistor T6. A source region S6 and a drain region D6 may be arranged on both sides of the channel region A6 of the sixth transistor T6. The source region S6 of the sixth transistor T6 may be connected to the drain region D1 of the first transistor T1.

A channel region A7 of the seventh transistor T7 may overlap the fourth gate signal line GBL (e.g., in the z-axis direction). A portion of the fourth gate signal line GBL that overlaps the channel region A7 of the seventh transistor T7 (e.g., in the z-axis direction) may be the gate electrode G7 of the seventh transistor T7. A source region S7 and a drain region D7 may be arranged on both sides of the channel region A7 of the seventh transistor T7. The drain region D7 of the seventh transistor T7 may be connected to the drain region D6 of the sixth transistor T6.

A channel region A8 of the eighth transistor T8 may overlap the fourth gate signal line GBL (e.g., in the z-axis direction). A portion of the fourth gate signal line GBL that overlaps the channel region A8 of the eighth transistor T8 (e.g., in the z-axis direction) may be the gate electrode G8 of the eighth transistor T8. A source region S8 and a drain region D8 may be arranged on both sides of the channel region A8 of the eighth transistor T8. The drain region D8 of the eighth transistor T8 may be connected to the source region S1 of the first transistor T1.

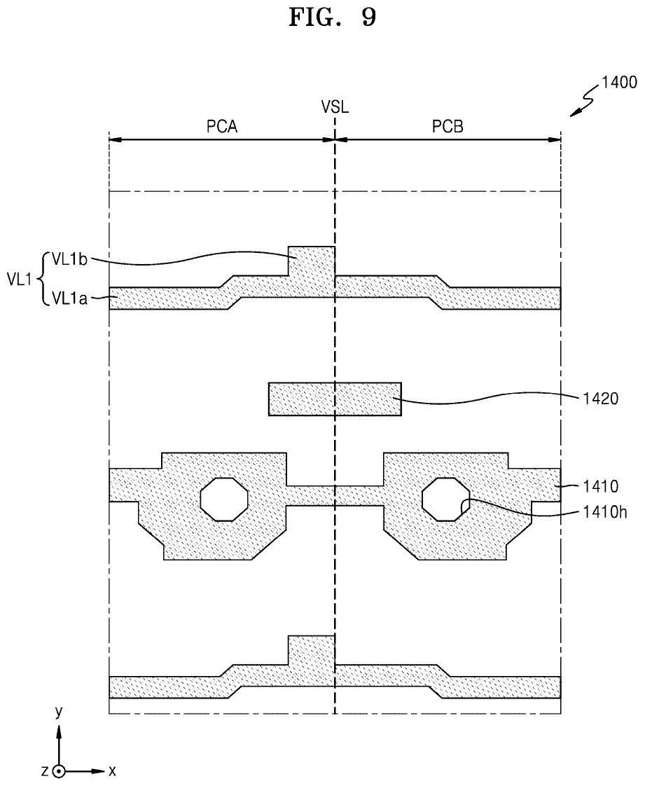

Referring to FIG. 9, a third conductive layer 1400 may be arranged on the second conductive layer 1300. At least one insulating layer may be arranged between the second conductive layer 1300 and the third conductive layer 1400 (e.g., in the z-axis direction). In an embodiment, the third conductive layer 1400 may include a conductive material including Mo, Al, Cu, Ti, or the like, and may have a multi-layered or single layer structure including the materials described above. In an embodiment, the third conductive layer 1400 may include a fifth conductive pattern 1410, a sixth conductive pattern 1420, and a first initialization voltage line VL1.

In an embodiment, the fifth conductive pattern 1410 may include a connection portion and a body portion, which extend longitudinally in the first direction (e.g., the x-axis direction). In an embodiment, the body portion of the fifth conductive pattern 1410 may overlap the second conductive pattern 1310 (e.g., in the z-axis direction) and may form a storage capacitor (see Cst of FIG. 5). For example, the second conductive pattern 1310 may be a first capacitor electrode (see CE1 of FIG. 5) of the storage capacitor Cst, and the fifth conductive pattern 1410 may be a second capacitor electrode (see CE2 of FIG. 5) of the storage capacitor Cst. The fifth conductive pattern 1410 may include a first hole 1410h exposing a portion of the second conductive pattern 1310.

In an embodiment, the sixth conductive pattern 1420 may be provided in an island type arrangement. The sixth conductive pattern 1420 may overlap the channel region A3 of the third transistor T3 (e.g., in the z-axis direction) to be described later.

In an embodiment, the first initialization voltage line VL1 may include a first portion VL1a extending longitudinally approximately in the first direction (e.g., the x-axis direction), and a second portion VL1b protruding from the first portion VL1a in the second direction (e.g., the y-axis direction). In an embodiment, the second portion VL1b of the first initialization voltage line VL1 may not be linearly symmetrical but may be arranged only in the first pixel area PCA. The first initialization voltage line VL1 may be configured to transmit the first initialization voltage (see VINT of FIG. 5) to pixel circuits arranged in the same pixel row.

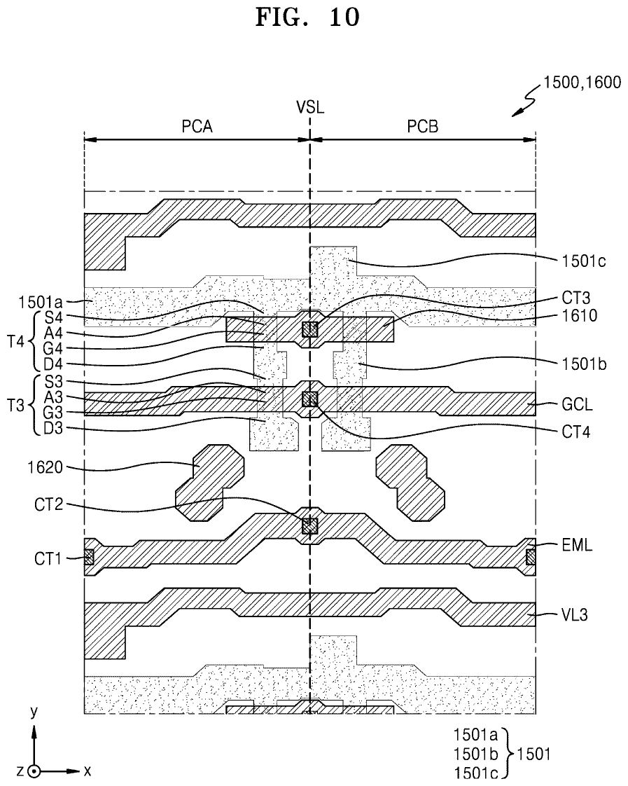

For convenience of description, FIG. 10 shows a second semiconductor layer 1500 and a fourth conductive layer 1600 overlapping each other (e.g., in the z-axis direction). Referring to FIG. 10, the second semiconductor layer 1500 may be disposed on the third conductive layer 1400, and the fourth conductive layer 1600 may be disposed on the second semiconductor layer 1500. At least one insulating layer may be disposed between the third conductive layer 1400 and the second semiconductor layer 1500 and between the second semiconductor layer 1500 and the fourth conductive layer 1600, respectively (e.g., in the z-axis direction).

In an embodiment, the second semiconductor layer 1500 may include an oxide-based semiconductor material, for example, an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cerium (Ce), and zinc (Zn). In an embodiment, the second semiconductor layer 1500 may be In—Ga—Zn—O (IGZO) or In—Sn—Ga—Zn—O (ITGZO).

The fourth conductive layer 1600 may include a conductive material including Mo, Al, Cu, Ti, or the like, and may have a multi-layered or single layer structure including the materials described above.

The second semiconductor layer 1500 may include a third semiconductor pattern 1501. In an embodiment, the third semiconductor pattern 1501 may include a first portion 1501a extending longitudinally in the first direction (e.g., the x-axis direction), second portions 1501b protruding from the first portion 1501a in the second direction (e.g., the y-axis direction), and a third portion 1501c protruding from the first portion 1501a in the second direction (e.g., the y-axis direction). In an embodiment, the second portions 1501b of the second semiconductor layer 1500 may be linearly symmetrical with respect to the virtual straight line VSL. In contrast, the third portion 1501c of the third semiconductor pattern 1501 may not be linearly symmetrical but may be arranged only in the second pixel area PCB.

In an embodiment, the second portion 1501b of the third semiconductor pattern 1501 may include a channel region A3 of the third transistor T3 and a channel region A4 of the fourth transistor T4. In an embodiment, the third semiconductor pattern 1501 may be integrally provided, and a source region and a drain region may be arranged on both side of each of the channel regions A3 and A4.

In an embodiment, the fourth conductive layer 1600 may include a seventh conductive pattern 1610, an eighth conductive pattern 1620, a third gate signal line GCL, an emission control signal line EML, and an on-bias voltage line VL3. Each of the third gate signal line GCL, the emission control signal line EML, and the on-bias voltage line VL3 may extend longitudinally substantially in the first direction (e.g., the x-axis direction). The third gate signal line GCL may be configured to transmit the third gate signal (see GC of FIG. 5) to pixels disposed in the same pixel row, and the emission control signal line EML may be configured to transmit the emission control signal (see EM of FIG. 5) to pixel circuits disposed in the same pixel row. The on-bias voltage line VL3 may be configured to transmit an on-bias voltage (see VOBS of FIG. 5) to pixel circuits arranged in the same pixel row.

A channel region A3 of the third transistor T3 may overlap the third gate signal line GCL (e.g., in the z-axis direction). A portion of the third gate signal line GCL that overlaps the channel region A3 of the third transistor T3 (e.g., in the z-axis direction) may be an upper gate electrode G3 of the third transistor T3. The third gate signal line GCL may be connected to the sixth conductive pattern 1420 of the third conductive layer 1400 through a contact hole CT4. The sixth conductive pattern 1420 may receive the third gate signal GC from the third gate signal line GCL to a lower gate electrode of the third transistor T3. A source region S3 and a drain region D3 may be arranged on both sides of the channel region A3 of the third transistor T3.

A channel region A4 of the fourth transistor T4 may overlap a seventh conductive pattern 1610 (e.g., in the z-axis direction). The seventh conductive pattern 1610 may be electrically connected to the second gate signal line GIL of the second conductive layer 1300 through the contact hole CT3. The seventh conductive pattern 1610 may receive the second gate signal GI from the second gate signal line GIL to an upper gate electrode G4 of the fourth transistor T5. A portion of the second gate signal line GIL that overlaps the channel region A4 of the fourth transistor T4 (e.g., in the z-axis direction) may be a lower gate electrode of the fourth transistor T4. A source region A4 and a drain region D4 may be arranged on both sides of the channel region A4 of the fourth transistor T4. The drain region D4 of the fourth transistor T4 may be connected to the source region S3 of the third transistor T3.

In an embodiment, the emission control signal line EML may be electrically connected to the third conductive pattern 1320 of the second conductive layer 1300 through a contact hole CT1, and may be electrically connected to the fourth conductive pattern 1330 of the second conductive layer 1300 through a contact hole CT2. The third conductive pattern 1320 may be a gate electrode G5 of the fifth transistor T5 and may receive the emission control signal EM from the emission control signal line EML. The fourth conductive pattern 1330 may be a gate electrode G6 of the sixth transistor T6 and may receive the emission control signal EM from the emission control signal line EML.

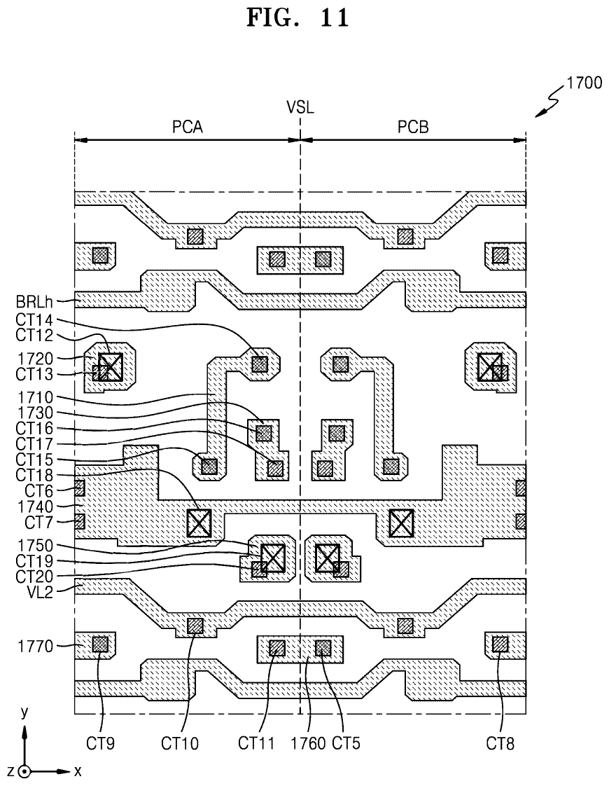

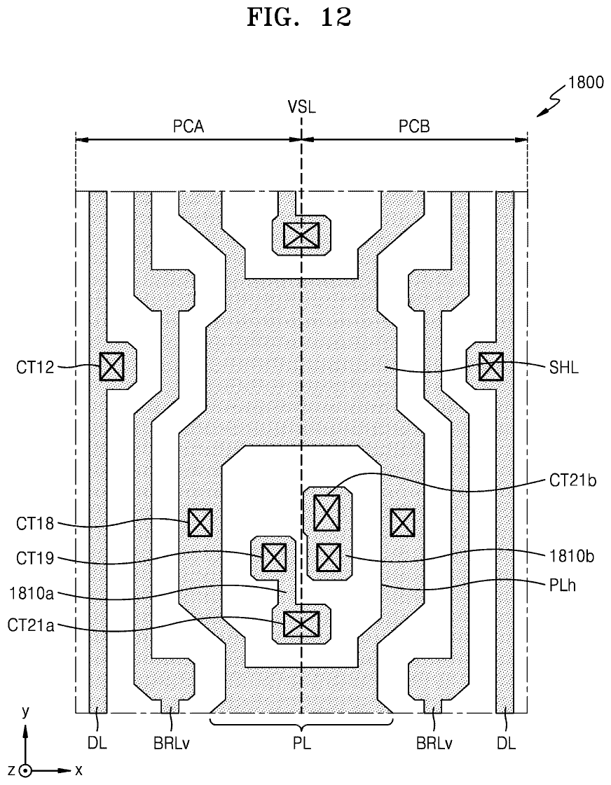

Referring to FIGS. 11 and 12, a fifth conductive layer 1700 may be disposed on the fourth conductive layer 1600, and a sixth conductive layer 1800 may be disposed on the fifth conductive layer 1700. At least one insulating layer may be disposed between the fourth conductive layer 1600 and the fifth conductive layer 1700 and between the fifth conductive layer 1700 and the sixth conductive layer 1800, respectively (e.g., in the z-axis direction).

In an embodiment, each of the fifth conductive layer 1700 and the sixth conductive layer 1800 may include a conductive material including Mo, Al, Cu, Ti, or the like, and may have a multi-layered or single layer structure including the materials described above. In an embodiment, each of the fifth conductive layer 1700 and the sixth conductive layer 1800 may have a multi-layered structure of Ti/Al/Ti.

In an embodiment, the fifth conductive layer 1700 may include a ninth conductive pattern 1710, a 10th conductive pattern 1720, an 11th conductive pattern 1730, a 12th conductive pattern 1740, a 13th conductive pattern 1750, a 14th conductive pattern 1760, a 15th conductive pattern 1770, a horizontal data connection line BRLh, and a second initialization voltage line VL2. In an embodiment, the sixth conductive layer 1800 may include a 16th−1 conductive pattern 1810a, a 16th−2 conductive pattern 1810b, a data line DL, a driving voltage line PL, and a vertical data connection line BRLv.

In an embodiment, the ninth conductive pattern 1710 may be electrically connected to the source region S3 of the third transistor T3 and the drain region D4 of the fourth transistor T4 through a contact hole CT14, and may be electrically connected to the second conductive pattern 1310 through a contact hole CT15. The source region S3 of the third transistor T3, the drain region D4 of the fourth transistor T4, the gate electrode G1 of the first transistor T1, and the first capacitor electrode (see CE1 of FIG. 5) of the storage capacitor (see Cst of FIG. 5) may be electrically connected through the ninth conductive pattern 1710.

In an embodiment, the 10th conductive pattern 1720 may be electrically connected to the source region S2 of the second transistor T2 through the contact hole CT13 and may be electrically connected to the data line DL of the sixth conductive layer 1800 through the contact hole CT12. The data line DL may extend longitudinally in the second direction (e.g., the y-axis direction) and may be configured to transmit a data signal (see Dm of FIG. 5) corresponding to pixel circuits arranged in the same pixel row. In an embodiment, the data line DL may overlap the channel region A5 of the fifth transistor T5 (e.g., in the z-axis direction). The source region S2 of the second transistor T2 may receive the data signal Dm from the data line DL through the 10th conductive pattern 1720.

The 11th conductive pattern 1730 may be electrically connected to the drain region D3 of the third transistor T3 through the contact hole CT16 and may be electrically connected to the drain region D1 of the first transistor T1 and the source region S6 of the sixth transistor T6 through the contact hole CT17. The drain region D3 of the third transistor T3, the drain region D1 of the first transistor T1, and the source region S6 of the sixth transistor T6 may be electrically connected to each other through the 11th conductive pattern 1730.

The 12th conductive pattern 1740 may include a connection portion and a body portion. The connection portion of the 12th conductive pattern 1740 may extend in the first direction (e.g., the x-axis direction) and may connect the body portion located in the first pixel area PCA and the body portion located in the second pixel area PCB to each other. The 12th conductive pattern 1740 may be electrically connected to the fifth conductive pattern 1410 of the third conductive layer 1400 through the contact hole CT6, may be electrically connected to the source region S5 of the fifth transistor T5 through the contact hole CT7, and may be electrically connected to the driving voltage line PL of the sixth conductive layer 1800 through the contact hole CT18. The source region S5 of the fifth transistor T5 and the second capacitor electrode (see CE2 of FIG. 5) of the storage capacitor (see Cst of FIG. 5) may receive the driving voltage (see ELVDD of FIG. 5) from the driving voltage line PL through the 12th conductive pattern 1740.

The 13th conductive pattern 1750 may be electrically connected to the drain region D6 of the sixth transistor T6 and the drain region D7 of the seventh transistor T7 through the contact hole CT20 and may be electrically connected to a 16th−1 conductive pattern 1810 or a 16th−2 conductive pattern 1810b of the sixth conductive layer 1800 through the contact hole CT19. Each of the 16th−1 conductive pattern 1810a and the 16th−2 conductive pattern 1810b may be electrically connected to the organic light-emitting diode (see OLED of FIG. 5) to be described later through the contact hole CT21. In an embodiment, the drain region D6 of the sixth transistor T6, the drain region D7 of the seventh transistor T7, and the organic light-emitting diode OLED may be electrically connected to each other through the 13th conductive pattern 1750 and the 16th−1 conductive pattern 1810a or the 13th conductive pattern 1750 and the 16th−2 conductive pattern 1810b.

In an embodiment, the 14th conductive pattern 1760 may be electrically connected to the source region S4 of the fourth transistor T4 through the contact hole CT5 and may be electrically connected to the first initialization voltage line VL1 through the contact hole CT11. For example, the 14th conductive pattern 1760 may electrically connect the third portion 1501c of the third semiconductor pattern 1501 to the second portion VL1b of the first initialization voltage line VL1. The source region S4 of the fourth transistor T4 may receive a first initialization voltage (see VINT of FIG. 5) from the first initialization voltage line VL1 through the 14th conductive pattern 1760. The 14th conductive pattern 1760 may be referred to as a connection electrode or a first connection electrode.

The 15th conductive pattern 1770 may be electrically connected to the on-bias voltage line VL3 through the contact hole CT9 and may be electrically connected to the source region S8 of the eighth transistor T8 through the contact hole CT8. The source region S8 of the eighth transistor T8 may receive an on-bias voltage (see VOBS of FIG. 5) from the on-bias voltage line VL3 through the 15th conductive pattern 1770.

A horizontal data connection line BRLh may extend longitudinally in the first direction (e.g., the x-axis direction). A vertical data connection line BRLv may extend in the second direction (e.g., the y-axis direction) crossing the first direction (e.g., the x-axis direction). The horizontal data connection line BRLh and the vertical data connection line BRLv shown in FIGS. 6, 11, and 12 are electrically separated from each other by at least one insulating layer, however, in some partial areas, the horizontal data connection line BRLh and the vertical data connection line BRLv corresponding to the horizontal data connection line BRLh may be electrically connected to each other through a contact hole. Similarly, in some pixel areas, the horizontal data connection line BRLh and the data line DL may be electrically connected to each other through a contact hole. The horizontal data connection line BRLh may be referred to as a first data connection line. The vertical data connection line BRLv may be referred to as a second data connection line.

The horizontal data connection line BRLh and the vertical data connection line BRLv may be a configuration corresponding to the data transmission line described with reference to FIGS. 3A and 4A. For example, in an embodiment the horizontal data connection line BRLh may be electrically connected to the data line DL and the vertical data connection line BRLv and may transmit a data signal (see Dm of FIG. 5). As described above, in some pixel areas in which the horizontal data connection line BRLh and the vertical data connection line BRLv are not arranged, dummy wirings (e.g., additional connection lines, auxiliary connection lines, etc.) having the same shape as each of the horizontal data connection line BRLh and the vertical data connection line BRLv may be disposed therein.

The second initialization voltage line VL2 may extend longitudinally in the first direction (e.g., the x-axis direction) and may be electrically connected to pixel circuits arranged in the same pixel row. The second initialization voltage line VL2 may be electrically connected to the source region S7 of the seventh transistor T7 through the contact hole CT10. The source region S7 of the seventh transistor T7 may receive the second initialization voltage (see VAINT of FIG. 5) from the second initialization voltage line VL2.

The driving voltage line PL may extend longitudinally in the second direction (e.g., the y-axis direction) and may overlap the first pixel area PCA and the second pixel area PCB. The driving voltage line PL may have a second hole PLh defined therein that overlaps the 14th conductive pattern 1760 and may include a shielding portion SHL. The 16th−1 conductive pattern 1810a and the 16th−2 conductive pattern 1810b may be arranged while overlapping the second hole PLh of the driving voltage line PL (e.g., in the z-axis direction). The shielding portion SHL of the driving voltage line PL may overlap the horizontal data connection line BRLh, the third transistor T3, and the fourth transistor T4 and may reduce an electrical effect between components below a second pixel electrode 1902 and the shielding portion SHL to be described later.

In an embodiment, the horizontal data connection line BRLh, the 14th conductive pattern 1760, and the second initialization voltage line VL2 may be arranged in the same layer. The 14th conductive pattern 1760 may be arranged between the horizontal data connection line BRLh and the second initialization voltage line VL2 (e.g., in the y-axis direction). As the 14th conductive pattern 1760 is offset and arranged in the second direction (e.g., the y-axis direction) from the first portion VL1a of the first initialization voltage line VL1, the horizontal data connection line BRLh may not bypass the 14th conductive pattern 1760 and may extend to overlap the shielding portion SHL of the driving voltage line PL (e.g., in the z-axis direction).

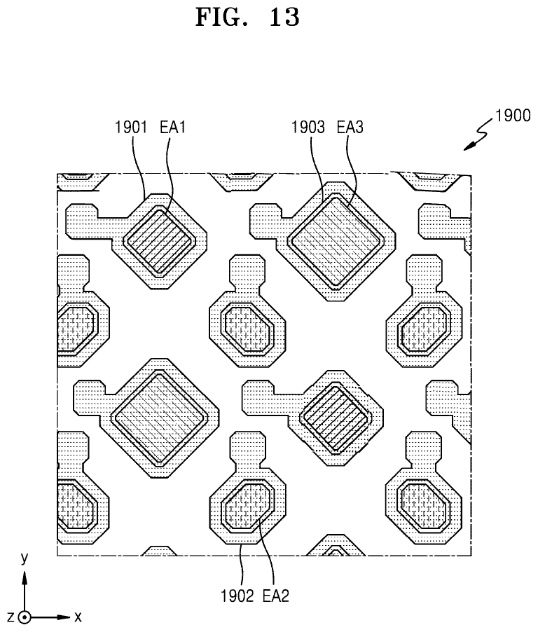

The seventh conductive layer 1900 may be arranged on the sixth conductive layer 1800. At least one insulating layer may be arranged between the sixth conductive layer 1800 and the seventh conductive layer 1900 (e.g., in the z-axis direction). FIG. 13 is an arrangement view for describing the arrangement of pixel electrodes 1901, 1902, and 1903. The pixel electrodes 1901, 1902, and 1903 may be repeatedly arranged in the first direction (e.g., the x-axis direction) and the second direction (e.g., the y-axis direction) according to certain patterns.

In an embodiment, the pixel electrodes 1901, 1902, and 1903 may be arranged in a Pentile™ arrangement (or a diamond arrangement). For example, in an embodiment a first emission area EA1 defined in the first pixel electrode 1901 may emit red light, a second emission area EA2 defined in the second pixel electrode 1902 may emit green light, and a third emission area EA3 defined in the third pixel electrode 1903 may emit blue light. The second pixel electrode 1902 may be disposed at each of rectangular vertices centering on the first pixel electrode 1901 or the third pixel electrode 1903.

Each of the first pixel electrode 1901 and the third pixel electrode 1903 may be electrically connected to the 16th−2 conductive pattern 1810b through a contact hole CT21b, and the second pixel electrode 1902 may be connected to the 16th−1 conductive pattern 1810a through a contact hole CT21a. The second pixel electrode 1902 may be arranged to overlap the shielding portion SHL of the driving voltage line PL (e.g., in the z-axis direction).

In an embodiment, the first pixel electrode 1901 and the third pixel electrode 1903 may have an approximately chamfered rectangular shape. The second pixel electrode 1902 may have an inclined octagonal shape. However, embodiments of the present disclosure are not necessarily limited thereto. The pixel electrodes 1901, 1902, and 1903 may be disposed in various forms such as a stripe arrangement, a mosaic arrangement, and the like, and each of the pixel electrodes 1901, 1902, and 1903 may have various shapes such as a polygonal shape, a circle, and an ellipse.

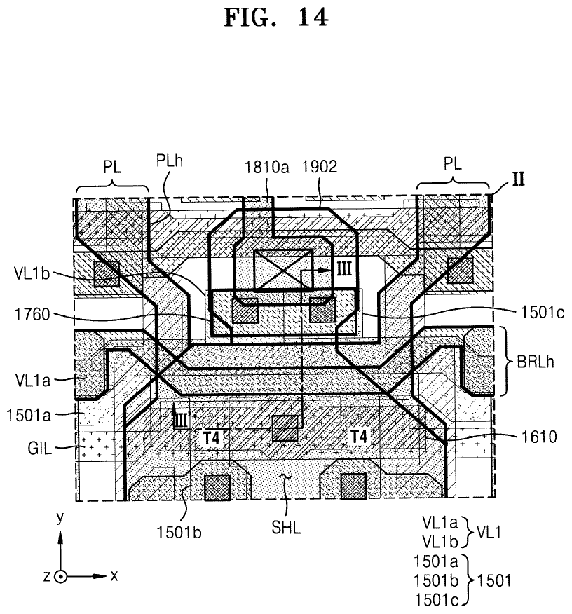

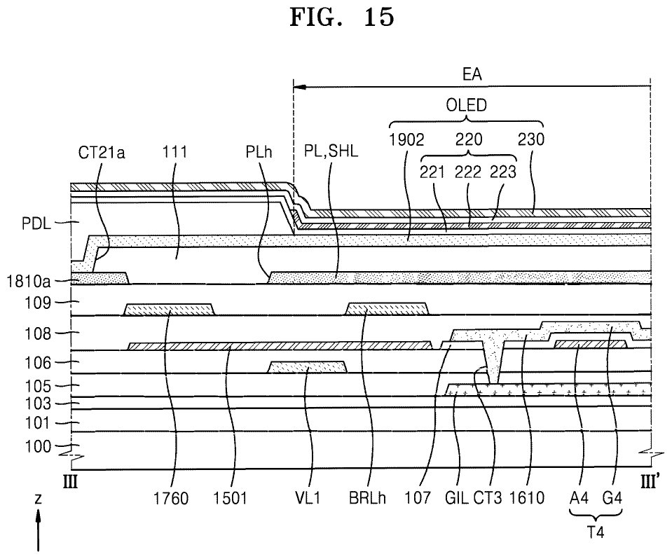

FIG. 14 is an enlarged plan view schematically illustrating a portion of the display apparatus shown in FIG. 6, and FIG. 15 is a cross-sectional view schematically illustrating a portion of the display apparatus shown in FIG. 14.

Referring to FIGS. 14 and 15, a first insulating layer 101 may be arranged on the substrate 100 (e.g., disposed directly thereon in the z-axis direction), and a second insulating layer 103 may be arranged on the first insulating layer 101 (e.g., disposed directly thereon in the z-axis direction). A first conductive layer (see 1100 of FIG. 7) may be arranged between the substrate 100 and the first insulating layer 101, and a first semiconductor layer (see 1200 of FIG. 8) may be arranged between the first insulating layer 101 and the second insulating layer 103 (e.g., in the z-axis direction).

The second conductive layer (see 1300 of FIG. 8) may be arranged on the second insulating layer 103, and the third conductive layer 1400 may include a second gate signal line GIL that extends longitudinally in the first direction (e.g., the x-axis direction).

The third insulating layer 105 may be arranged on the second conductive layer 1300, and the third conductive layer (see 1400 of FIG. 9) may be arranged on the third insulating layer 105. The third conductive layer 1400 may include a first initialization voltage line VL1 that extends longitudinally in the first direction (e.g., the x-axis direction). The first initialization voltage line VL1 may include a first portion VL1a extending longitudinally in the first direction (e.g., the x-axis direction), and a second portion VL1b protruding from the first portion VL1a in the second direction (e.g. the y-axis direction).

The fourth insulating layer 106 may be arranged on the third conductive layer 1400, and the second conductive layer (see 1500 of FIG. 10) may be arranged on the fourth insulating layer 106. The second semiconductor layer 1500 may include a third semiconductor pattern 1501, and the third semiconductor pattern 1501 may include a first portion 1501a extending longitudinally in the first direction (e.g., the x-axis direction), second portions 1501b protruding from the first portion 1501a in the second direction (e.g., the y-axis direction), and a third portion 1501c. The second portion 1501b of the third semiconductor pattern 1501 may include a channel region A4 of the fourth transistor T4.

As shown in FIG. 14, the second semiconductor layer 1500 may protrude from the first portion VL1a of the first initialization voltage line VL1 so that the first portion VL1a of the first initialization voltage line VL1 may overlap the first portion 1501a of the third semiconductor pattern 1501 (e.g., in the z-axis direction) and the second portion VL1b of the first initialization voltage line VL1 may not overlap the first portion 1501a of the third semiconductor pattern 1501 (e.g., in the z-axis direction).

The fifth insulating layer 107 may be arranged on the second semiconductor layer 1500, and the fourth conductive layer (see 1600 of FIG. 10) may be arranged on the fifth insulating layer 107. In an embodiment, the fifth insulating layer 107 may have a shape corresponding to the shape of the fourth conductive layer 1600 in a plan view.

The fourth conductive layer 1600 may include a seventh conductive pattern 1610. The seventh conductive pattern 1610 may be electrically connected to the second gate signal line GIL of the second conductive layer 1300 through the contact hole CT3 passing through the third insulating layer 105, the fourth insulating layer 106, and the fifth insulating layer 017. The seventh conductive pattern 1610 may receive the second gate signal GI from the second gate signal line GIL to an upper gate electrode G4 of the fourth transistor T5. In an embodiment, a portion of the second gate signal line GIL that overlaps the channel region A4 of the fourth transistor T4 may be a lower gate electrode of the fourth transistor T4.

The sixth insulating layer 108 may be arranged on the fourth conductive layer 1600, and the fifth conductive layer (see 1700 of FIG. 11) may be arranged on the sixth insulating layer 108. The fifth conductive layer 1700 may include a 14th conductive pattern 1760 and a horizontal data connection line BRLh.

The 14th conductive pattern 1760 may be a connection electrode that electrically connects the first initialization voltage line VL1 of the third conductive layer 1400 and the third semiconductor pattern 1501 of the second semiconductor layer 1500 to each other. For example, the 14th conductive pattern 1760 may be configured to electrically connect the second portion VL1b of the first initialization voltage line VL1 and the third portion 1501c of the third semiconductor pattern 1501 to each other.

The horizontal data connection line BRLh may be a configuration corresponding to the horizontal connection line described with reference to FIGS. 3B and 4B. The horizontal data connection line BRLh may be electrically connected to the data line (see DL of FIG. 12) and the vertical data connection line (see BRLv of FIG. 12). A horizontal data connection line BRLh may extend in the first direction (e.g., the x-axis direction).

In an embodiment, each of the first insulating layer 101 through the sixth insulating layer 108 may be a single layer or a multi-layered structure including an inorganic material such as silicon oxide, silicon nitride, silicon oxynitride or the like.

The seventh insulating layer 109 may be arranged on the fifth conductive layer 1700, and the sixth conductive layer (see 1800 of FIG. 12) may be arranged on the seventh insulating layer 109. In an embodiment, the sixth conductive layer 1800 may include a 16th−1 conductive pattern 1810a and a driving voltage line PL.

The driving voltage line PL may define a second hole PLh that overlaps the 14th conductive pattern 1760 (e.g., in the z-axis direction) and may include a shielding portion SHL that overlaps the horizontal data connection line BRLh (e.g., in the z-axis direction). The shielding portion SHL of the driving voltage line PL may be arranged between the horizontal data connection line BRLh and the second pixel electrode 1902, and may reduce parasitic capacitance between the horizontal data connection line BRLh and the second pixel electrode 1902.

The 16th−1 conductive pattern 1810a may be a connection electrode that is electrically connected to the second pixel electrode 1902 of the seventh conductive layer (see 1900 of FIG. 13) through the contact hole CT21a passing through the seventh insulating layer 109. For example, the 16th−1 conductive pattern 1810a may be referred to as a second connection electrode. The 16th−1 conductive pattern 1810 may overlap the second hole PLh of the driving voltage line PL (e.g., in the z-axis direction).

The 14th conductive pattern 1760 may be offset in the second direction (e.g., the y-axis direction) from the first portion VL1a of the first initialization voltage line VL1 and the first portion 1501a of the third semiconductor pattern 1501 and may be arranged between the 16th−1 conductive pattern 1810a and the horizontal data connection line BRLh. Thus, the horizontal data connection line BRLh may be sufficiently spaced apart from the 16th−1 conductive pattern 1810a in the second direction (e.g., the y-axis direction) and may reduce parasitic capacitance between the horizontal data connection line BRLh and the 16th−1 conductive pattern 1810a.

The eighth insulating layer 111 may be arranged on the sixth conductive layer 1800, and the organic light-emitting diode OLED may be arranged on the eighth insulating layer 111. Each of the seventh insulating layer 109 and the eighth insulating layer 111 may be a single layer or multi-layered structure including an inorganic material and/or an organic material. In an embodiment, the inorganic material may include silicon oxide, silicon nitride or silicon oxynitride, and the organic material may include acrylic-based resin, benzocyclobutene (BCB) or hexamethyldisiloxane (HMDSO).

In an embodiment, the organic light-emitting diode OLED shown in FIG. 15 may be an organic light-emitting diode OLED that emits green light. However, embodiments of the present disclosure are not necessarily limited thereto. The organic light-emitting diode OLED may include a second pixel electrode 1902, an opposite electrode 230 that faces the second pixel electrode 1902, and an intermediate layer 220 between the second pixel electrode 1902 and the opposite electrode 230.

The second pixel electrode 1902 may be a (semi-)transparent electrode or a reflective electrode. In an embodiment, the second pixel electrode 1902 may include a reflective layer including Ag, Mg, Al, Pt, Pd, Au, Ni, Nd, Ir, Cr, and a compound thereof, and a transparent or a semi-transparent electrode layer formed on the reflective layer. In an embodiment, the transparent or semi-transparent electrode layer may include at least one material selected from the group consisting of indium tin oxide (ITO), indium zinc oxide (IZO), zinc oxide (ZnO), indium oxide (In₂O₃), indium gallium oxide (IGO), and aluminum zinc oxide (AZO). In an embodiment, the second pixel electrode 1902 may include ITO/Ag/ITO.

The second pixel electrode 1902 may be arranged to overlap the shielding portion SHL of the driving voltage line PL (e.g., in the z-axis direction). The second pixel electrode 1902 may overlap the horizontal data connection line BRLh, and the shielding portion SHL of the driving voltage line PL may be arranged between the horizontal data connection line BRLh and the second pixel electrode 1902 (e.g., in the z-axis direction). Similarly, the second pixel electrode 1902 may overlap the third transistor (see T3 of FIG. 10) and the fourth transistor T4, and the shielding portion SHL of the driving voltage line PL may be arranged between the third transistor T3, the fourth transistor T4 and the second pixel electrode 1902 (e.g., in the z-axis direction).

In an embodiment, a pixel-defining layer PDL may be arranged on the eighth insulating layer 111 to cover the edge of the second pixel electrode 1902. The pixel-defining layer PDL may include an opening for exposing a portion of the second pixel electrode 1902. An emission area EA of the organic light-emitting diode OLED may be defined by the opening of the pixel-defining layer PDL.

The pixel-defining layer PDL may increase a distance between the edge of the second pixel electrode 1902 and the opposite electrode 230, thereby preventing an arc etc. from occurring in the edge of the second pixel electrode 1902. In an embodiment, the pixel-defining layer PDL may include one or more organic insulating materials selected from the group consisting of polyimide, polyamide, an acrylic-based resin, BCB, and a phenol-based resin. In an embodiment, the pixel-defining layer PDL may include a light blocking material and may be colored black. The light blocking material may include carbon black, carbon nanotubes, a resin or paste including a black dye, metal particles, such as Ni, Al, Mo and alloys thereof, metal oxide particles (e.g., chromium oxide), or metal nitride particles (e.g., chromium nitride).

The intermediate layer 220 may be disposed on the second pixel electrode 1902. The intermediate layer 220 may include a light-emitting layer 222. The light-emitting layer 222 may include a polymer or a low molecular weight organic material emitting light of a certain color. In an embodiment, the light-emitting layer 222 may further include, in addition to various organic materials, a metal-containing compound such as an organometallic compound, an inorganic material such as a quantum dot, and the like. In an embodiment, the light-emitting layer 222 may be patterned to correspond to the second pixel electrode 1902.

A first functional layer 221 may be arranged between the light-emitting layer 222 and the second pixel electrode 1902, and a second functional layer 223 may be arranged between the light-emitting layer 222 and the opposite electrode 230. The first functional layer 221 may be a hole transport layer (HTL). Alternatively, the first functional layer 221 may include a hole injection layer (HIL) and a hole transport layer. The second functional layer 223 may include an electron transport layer (ETL) and/or an electron injection layer (EIL). The first functional layer 221 and the second functional layer 223 may be integrally formed to correspond to a plurality of organic light-emitting diodes OLEDs. However, embodiments of the present disclosure are not necessarily limited thereto. For example, the first functional layer 221 or the second functional layer 223 may be omitted in some embodiments.

The opposite electrode 230 may be disposed on the light-emitting layer 222. In an embodiment, the opposite electrode 230 may include lithium (Li), Ag, Mg, Al, Al—Li, calcium (Ca), Mg—In, Mg—Ag, yitterbium (Yb), Ag—Yb, ITO, IZO, or any combination thereof. The opposite electrode 230 may be a transmissive electrode, a semi-transmissive electrode, or a reflective electrode. In an embodiment, the opposite electrode 230 may be integrally formed to correspond to a plurality of organic light-emitting diodes OLEDs.

In a comparative example, when the 14th conductive pattern is disposed to overlap the first portion of the first initialization voltage line (e.g., in the z-axis direction), the horizontal data connection line may be disposed adjacent to the 16th−1 conductive pattern to bypass the 14th conductive pattern. In this case, the horizontal data connection line deviates from the shielding portion of the driving voltage line, and may form parasitic capacitance with overlapping pixel electrodes and 16th−1 conductive patterns. Thus, the brightness of some pixels may increase or decrease due to the coupling between the horizontal data connection line and the pixel electrode, causing specks in an image displayed by the display apparatus.

On the other hand, in embodiments of the present disclosure, a shielding portion SHL of the driving voltage line PL is disposed between the horizontal data connection line BRLh and the second pixel electrode 1902 (e.g., in the z-axis direction), and as the horizontal data connection line BRLh and the 16th−1 conductive pattern 1810a are sufficiently spaced apart from each other in the second direction (e.g., the y-axis direction), a display apparatus capable of displaying high-quality images by reducing brightness deviation between pixels can be implemented.

According to an embodiment of the present disclosure as described above, a display apparatus that may display high-quality images by reducing parasitic capacitance between the data connection line and the pixel electrode can be implemented. Of course, the scope of embodiments of the present disclosure is not limited by these effects.

It should be understood that embodiments of the present disclosure described herein should be considered in a descriptive sense only and not for purposes of limitation. Descriptions of features or aspects within each embodiment should typically be considered as available for other similar features or aspects in other embodiments. While one or more embodiments of the present disclosure have been described with reference to the figures, it will be understood by those of ordinary skill in the art that various changes in form and details may be made therein without departing from the spirit and scope of the present disclosure.

What is claimed is:

1. A display apparatus comprising:
a first conductive layer disposed on a substrate, the first conductive layer comprising a first initialization voltage line extending in a first direction;
a first semiconductor layer disposed on the first conductive layer;
a second conductive layer disposed on the first semiconductor layer, the second conductive layer comprising a first gate electrode;
a third conductive layer disposed on the second conductive layer, the third conductive layer comprising a first connection electrode electrically connecting the first semiconductor layer and the first initialization voltage line to each other and a first data connection line extending in the first direction; and
a fourth conductive layer disposed on the third conductive layer, the fourth conductive layer comprising a driving voltage line extending in a second direction crossing the first direction and a second data connection line,
wherein the driving voltage line has a hole defined therein, the hole overlaps the first connection electrode, the driving voltage line includes a shielding portion that overlaps the first data connection line.

2. The display apparatus of claim 1, wherein:
the first initialization voltage line comprises a first portion and a second portion protruding from the first portion in the second direction;
the first semiconductor layer comprises a first portion extending in the first direction and a second portion protruding from the first portion in the second direction; and
the first connection electrode electrically connects the second portion of the first initialization voltage line and the second portion of the first semiconductor layer to each other.

3. The display apparatus of claim 2, wherein the first portion of the first initialization voltage line overlaps the first portion of the first semiconductor layer.

4. The display apparatus of claim 1, wherein the fourth conductive layer further comprises a second connection electrode that overlaps the hole, and the first connection electrode is disposed between the second connection electrode and the first data connection line.

5. The display apparatus of claim 4, further comprising a fifth conductive layer disposed on the fourth conductive layer, the fifth conductive layer comprising a pixel electrode, wherein the pixel electrode is electrically connected to the second connection electrode.

6. The display apparatus of claim 5, wherein:
the pixel electrode overlaps the first data connection line; and
the shielding portion is disposed between the pixel electrode and the first data connection line.

7. The display apparatus of claim 1, wherein:
the third conductive layer further comprises a second initialization voltage line extending in the first direction; and
the first connection electrode is disposed between the first data connection line and the second initialization voltage line.

8. The display apparatus of claim 1, wherein:
the fourth conductive layer further comprises a data line extending in the second direction; and the first data connection line is electrically connected to the data line and the second data connection line.

9. The display apparatus of claim 8, wherein:
the substrate comprises a display area and a peripheral area outside the display area; and
the first data connection line is electrically connected to the data line in the display area.

10. The display apparatus of claim 1, further comprising a second semiconductor layer disposed between the substrate and the first conductive layer, wherein the first semiconductor layer comprises an oxide-based semiconductor material, and the second semiconductor layer comprises a silicon-based semiconductor material.

11. A display apparatus comprising:
a plurality of pixels:
a first data connection line extending in a first direction;
a second data connection line extending in a second direction crossing the first direction; and
a driving voltage line extending in the second direction, the driving voltage line having a hole defined therein and a shielding portion overlapping the first data connection line,
wherein each of the plurality of pixels comprises:
a light-emitting diode comprising a pixel electrode, an opposite electrode, and an intermediate layer between the pixel electrode and the opposite electrode;
a first transistor comprising a first semiconductor layer and a first gate electrode on the first semiconductor layer;
a second transistor electrically connected between a data line and the first transistor;
a third transistor electrically connected between a first initialization voltage line and the first gate electrode;
a fourth transistor electrically connected between the driving voltage line and the first transistor;
a fifth transistor electrically connected to the first transistor and the light-emitting diode; and
a first connection electrode electrically connecting the first initialization voltage line and the third transistor to each other, the first connection electrode overlapping the hole.

12. The display apparatus of claim 11, wherein:
each of the plurality of pixels further comprises a second connection electrode electrically connected between the pixel electrode and the fifth transistor; and
the second connection electrode overlaps the hole.

13. The display apparatus of claim 12, wherein the first connection electrode is disposed between the second connection electrode and the first data connection line.

14. The display apparatus of claim 11, wherein:
the pixel electrode overlaps the first data connection line;
and the shielding portion is disposed between the pixel electrode and the first data connection line.

15. The display apparatus of claim 14, wherein the light-emitting diode emits green light.

16. The display apparatus of claim 11, wherein the first data connection line is disposed in a same layer as the first connection electrode.

17. The display apparatus of claim 11, wherein each of the plurality of pixels further comprises a sixth transistor electrically connected between a second initialization voltage line and the light-emitting diode.

18. The display apparatus of claim 17, wherein:
the second initialization voltage line extends in the first direction; and
the first connection electrode is disposed between the second initialization voltage line and the first data connection line.

19. The display apparatus of claim 11, wherein the first data connection line is electrically connected to the data line and the second data connection line.

20. The display apparatus of claim 11, further comprising an on-bias voltage line extending in the first direction, wherein each of the plurality of pixels further comprises a seventh transistor electrically connected between the on-bias voltage line and the first transistor.
